(19) United States
(12) Patent Application Publication
(10) Pub. No.: US 2025/0165887 A1
(43) Pub. Date: May 22, 2025

(54) METHOD FOR IMPROVING THE EFFICIENCY AND/OR INCREASING THE OPERATIONAL SCOPE OF A SYSTEM FOR PRESSURIZED FLUID COMPRISING A PRESSURIZED PIPING NETWORK UNDER DYNAMIC LOAD

(71) Applicant: ATLAS COPCO AIRPOWER, NAAMLOZE VENNOOTSCHAP, Wilrijk (BE)

(72) Inventors: Philippe GEUENS, Wilrijk (BE); Filip DE VOS, Wilrijk (BE)

(73) Assignee: ATLAS COPCO AIRPOWER, NAAMLOZE VENNOOTSCHAP, Wilrijk (BE)

(21) Appl. No.: 18/835,281

(22) PCT Filed: Jan. 17, 2023
(86) PCT No.: PCT/IB2023/050395

§ 371 Date: Aug. 1, 2024

(30) Foreign Application Priority Data
Feb. 9, 2022 (BE) BE2022/5085

(51) Int. Cl. G06Q 10/0631

(52) U.S. Cl. CPC G06Q 10/06313

(57) ABSTRACT

Method for improving the efficiency of a system for pressurized fluid which includes a piping network which is provided with an inlet and multiple pipe outlets, subjected to a varying load. The method including the evaluation of one or more virtual rearrangements of the system, which involves: a calculation of potential financial savings (PFS), which calculation possibly involves a measurement of pressures in the system; an evaluation of the potential financial savings (PFS); and, if there are positive potential financial savings (PFS) proposing one or more virtual rearrangements for implementation to a user.

### TECHNICAL FIELD

The present invention relates to the field of systems for pressurized fluid comprising a pressurized piping network, such as a pneumatic network. Such a system for pressurized fluid comprises a piping network with at least one main pipe inlet through which a pressurized fluid is supplied to the piping network for example by means of a pressurizing machine of the system for pressurized fluid, such as a compressor, and one or more pipe outlets through which pressurized fluid is delivered to one or more corresponding user devices or appliances which are located at user locations spaced apart from one another. The pressurized fluid taken by the different user devices or appliances varies over time, resulting in a dynamic load at the pipe outlets of the piping network.

### BACKGROUND

In many applications a pressurized fluid, mostly pressurized air, is used to drive certain pneumatically and/or hydraulically driven user devices or appliances, such as manufacturing or servicing tools, robots, machines, brakes and so on.

These pneumatically and/or hydraulically driven tools can be manually manipulated tools such as pneumatically and/or hydraulically driven wrenches, torque tools, screwdrivers, drills, grinders, sanders, polishers, percussive tools, compression tools, air motors, jacks, lifting tools and so on.

In other cases, the tools or machines are automatically manipulated tools or machines, such as pneumatically and/or hydraulically driven robot arms or robots, or computer-controlled manufacturing benches, which comprise pneumatically and/or hydraulically driven tools or arms that automatically execute the required actions and movements.

The amount of pressurized fluid power needed by said tools or machines differs very much from application to application. Different types of tools or machines have different nominal, maximal and minimal power needs. Also, during one operation with such a machine or tool the power needs vary according to the load exerted on the machine or tool or the resistance felt by the machine or tool.

Multiple such user devices or appliances driven by a pressurized fluid are often used simultaneously at locations which are spaced from one another at distances which can be large or very large (up to several 100 meters or kilometers) or which can be smaller (meters or several 10 meters) depending on the application.

For example, in certain manufacturing plants or assembly lines the manufacturing or assembly of a product requires different processing stages which are executed at different workstations, distributed over the entire surface of the plant or along the assembly line. Pre-processed parts of the product or semi-finished products are passed from workstation to workstation until a finished product is achieved. The workstations are therefore often placed in consecutive order in accordance with the sequence of the processing stages.

Also, in service centers or workshops for maintenance or for reparation of machines or vehicles, service operators typically work simultaneously at different posts spread over the entire service center or workshop for the reparation or maintenance of the concerned machine or vehicle.

In the construction industry or in mining operations, teams are often working at locations which are dispersed and widespread over the construction site or mining plant for executing often quite heavy tasks.

For providing pressurized fluid, usually pressurized air, to the different user locations, posts, workstations and so on, where user devices or appliances need the pressurized fluid for driving tools or machines, usually a single source or a limited number of sources of pressurized fluid is used.

Typically, such a source of pressurized fluid is a pressurizing machine that pressurizes an incoming non-pressurized fluid into an outgoing pressurized fluid. Such a pressurizing machine can for example be a compressor for compressing air at atmospheric pressure into air at a higher pressure. The pressurizing machine can also by a pump or any other machine by which a fluid can be pressurized.

The source of pressurized fluid can also be a combination of pressurizing machines or a combination of a pressurizing machine and a pressure vessel, put in series after one another, and so on.

In another example, it is also possible that the source of pressurized fluid is not a pressurizing machine, but an existing source of pressurized fluid, such as the water in a lake behind a barrage dam.

In order to connect the single source or limited number of sources of pressurized fluid with the different user devices and appliances, which need pressurized fluid, and which are spaced from one another at different user locations such as workstations, service posts, mining sites, and so on, a piping network is usually provided.

This piping network has at least one main pipe inlet, which is connected to the single source or limited number of sources of pressurized fluid.

As a rule, a main pipe piece extends from the main pipe inlet. This main pipe piece is branched into several pipe branches, which can also be further branched into pipe subbranches and so on, resulting in a number of pipe branches and pipe subbranches corresponding to the number of user locations to which pressurized fluid has to be provided.

These pipe branches and pipe subbranches are ending in a pipe outlet and the concerned user devices or appliances at the different user locations are connected to such a pipe outlet.

It is a known phenomenon that during transport of pressurized fluid from the main pipe inlet of such a piping network to an afore-mentioned pipe outlet a certain pressure drop occurs.

The pressure drop experienced at a certain pipe outlet is the difference between the fluid pressure present at the main pipe inlet and the fluid pressure experienced at the concerned pipe outlet.

This pressure drop is usually different for the different pipe outlets and depends on several factors and varies over time due to changing demands at the pipe outlets during operation.

The pressure drop is mainly caused by friction loss of the fluid during flow in the pipe.

A very important factor influencing said pressure drop is the flow rate of fluid or the velocity of the fluid through the pipe piece concerned.

Another factor that plays a certain role is the viscosity of the fluid.

Still another important factor that influences the pressure drop between the main pipe inlet and a certain pipe outlet of the piping network, is the pipe length of the concerned pipe piece between the main pipe inlet and the concerned pipe outlet.

Still other factors influencing said pressure drop are the roughness of the pipe in the concerned pipe piece, the diameter of the concerned pipe piece or changes in diameter in the concerned pipe piece between the main pipe inlet and the concerned pipe outlet.

Also, the number of bends in the concerned pipe piece, the presence of other mechanical components such as valves, flow meters, couplings, and so on, in the concerned pipe piece play an important role.

Still another factor that possibly influences the pressure or pressure drop is a variation of the fluid pressure at the main pipe inlet.

For example, when the demand of pressurized fluid at the totality of pipe outlets is very big, it is possible that the source of pressurized fluid cannot follow this total demand of pressurized fluid at the main pipe inlet and it is therefore possible that the fluid pressure at this main pipe inlet temporarily decreases, until the demand corresponds again with or is lower than the capacity of delivering pressurized fluid by the source of pressurized fluid.

In short, it is rather difficult or almost impossible to predict the varying pressure or pressure drops in a precise way at all the pipe outlets.

Furthermore, it is important to understand that some user devices or appliances connected to a pipe outlet of the piping network often require a minimal required fluid pressure at their inlet to be functional.

This means that the inlet pressure at the main pipe inlet should be at all times sufficiently high so that, when the pressure drops in the pipe pieces to the different pipe outlets are taken into account, there is still enough outlet pressure left at every and each pipe outlet and at each instance during the time of operation at the different user locations.

Or from another point of view, the pressure drops occurring between the main pipe inlet and the pipe outlets should not exceed a certain level so that the pressure at the pipe outlets is still sufficiently high, suitable for the concerned appliances that demand pressurized fluid at these pipe outlets.

This outlet pressure should in any circumstance at least be higher at each such user location than the minimum pressure required at the concerned user location so to provide pressurized fluid at a pressure which is sufficiently high, so that the concerned user devices or appliances can still function adequately, even when they are used at their highest load.

The needed inlet pressure at the main pipe inlet of the piping network could for example be determined theoretically by calculating what this needed inlet pressure should be in circumstances wherein the maximum load is simultaneously applied at all the pipe outlets or user locations.

In practice however, this situation of a maximal load of the piping network wherein simultaneously at all the user locations a maximal load is applied, will never or almost never exist.

Indeed, in normal circumstances during operation pressurized fluid is taken during certain periods at some of the pipe outlets, while other pipe outlets stay closed. During other periods of the operation other pipe outlets might open or some of the formerly open pipe outlets might close.

Furthermore, even the load taken at each of the pipe outlets in the non-closed situation of such a pipe outlet is usually varying or fluctuating during operation and such a load is usually not equal to the maximally allowable load during the entire duration of the operation.

As a result, a needed inlet pressure calculated theoretically in the above-mentioned way will be in practice unnecessarily high resulting in energy waste.

One can easily understand that it is not easy to determine how high the inlet pressure at the main pipe inlet should in practice at least be during operation, so that the needed load can be taken at the different pipe outlets in a safe way and without interruption of the operations at any of the user locations due to a lack of pressure at a concerned pipe outlet.

Obviously, when the source of pressurized fluid, which supplies the needed inlet pressure at the main pipe inlet of the piping network, comprises a pressurizing machine such as a compressor or pump, energy, for example electric energy, is needed to drive the pressurizing machine. The inlet pressure of the piping network is in that case of course the same as the outlet pressure of the pressurizing machine.

A lot of energy can be saved when the outlet pressure of the pressurizing machine or the inlet pressure of the piping network can be decreased and, consequently, also the costs related to the supply of energy can be reduced significantly.

In particular, the following formula gives an idea of the cost reduction obtained when a pressure reduction of Δp at the outlet of the pressurizing machine can be applied:

$$Cost reduction = ( \frac{Δ p}{0.1} ) \times V \times {R}_{h} \times 0.35 \times 0.007 \times {C}_{e}$$

The different parameters are:
Δp=pressure reduction at the outlet of the compressor
V=volume flow rate
Rₕ=running hours
Cₑ=cost of electricity

According to the state of the art a good method for improving or optimizing the energy and cost efficiency and/or increasing the operational scope of a system for pressurized fluid with a pressurized piping network which is subject to varying load at multiple pipe outlets of the piping network is not yet existing.

In particular, there is no good known method for setting the inlet pressure at the main piping inlet of the piping network at an optimized inlet pressure in a way which is adapted to the varying demands of pressurized fluid occurring in reality at the different pipe outlets of the piping network during operation.

From the above it is also clear that the design itself of such a system for pressurized fluid and its pressurized piping network influences a lot the pressure drops occurring between the main pipe inlet and the concerned pipe outlets, and, as a consequence, also the energy efficiency or energy consumption of the system for pressurized fluid or the availability of sufficiently high pressure at the pipe outlets of the piping network, which influences its operational scope.

For example, a pressure drop experienced between the main pipe inlet and one or more of the pipe outlets can be reduced by increasing the inner diameter of a part of the piping network between the main pipe and the concerned pipe outlet(s).

Another way of reducing pressure drop occurring between the main pipe inlet and one or more of the pipe outlets by changing the design, is to include a local pressure vessel in a part of a part of the piping network between the main pipe and the concerned pipe outlet(s).

Pressure drops in the system for pressurized fluid due to friction losses in pipes and other elements of the piping network can be reduced and the efficiency and/or the operational scope of the system of the system can be increased by still other means, such as by applying pipes with reduced roughness, by reduction of bends and other flow restricting elements in the piping network, by reducing the pipe length between the pressurizing machine at the main pipe inlet and the pipe outlets of the piping network and so on.

According to the state of the art, no good method exists to evaluate possible adaptations of an existing piping network for optimizing the energy and cost efficiency and/or for increasing the operational scope of the system for pressurized fluid in which the pressurized piping network is incorporated.

### SUMMARY OF THE INVENTION

The present invention aims to provide a method for optimizing or improving the efficiency of a system for pressurized fluid, such as a compressed air system, comprising a pressurized piping network that is subjected to a varying load, this of course with the intention of minimizing energy costs related to the passage of pressurized fluid through the piping network.

In particular, it is a possible aim of the present invention to develop a method by which pressure drops can be evaluated occurring in an existing pressurized piping network during operation with the piping network for delivery of pressurized fluid to user locations and to look for possibilities by which the needed inlet pressure at the main pipe inlet of the piping network can be decreased.

Another possible aim of the invention is to come to a method for evaluating possible modifications to an existing piping network of a system for pressurized fluid by which pressure drops can be reduced or lack of sufficiently high pressure at pipe outlets can be avoided with the intention to optimize the energy and cost efficiency and/or to increase the operational scope of the concerned system for pressurized fluid, whereby installation costs and financial gains from reduced energy costs are evaluated with respect to one another.

To this end, the present invention relates to a method for improving the efficiency and/or increasing the operational scope of a system for pressurized fluid which comprises a pressurized piping network which is provided with a main pipe inlet and multiple pipe outlets which are located at user locations which are spaced from one another, wherein at the main pipe inlet of the piping network an inlet pressure is provided by a source of pressurized fluid of the system for pressurized fluid and wherein the piping network is subjected to a varying load at the pipe outlets due to varying demands of pressurized fluid during operation of user devices or appliances connected to the pipe outlets at the user locations, wherein the method comprises the evaluation of one or more virtual rearrangements of the system, which involves:
a calculation of potential financial savings (PFS), due to an increase in energy efficiency or a decrease in energy consumption caused by such a rearrangement of the system versus costs for rearranging the system, which possibly involves a measurement of pressures in the system;
an evaluation of the potential financial savings (PFS); and,
if there are positive potential financial savings (PFS) proposing one or more virtual rearrangements for implementation to a user.

A great advantage of such a method according to the invention is that it allows for an improvement or optimization of the efficiency and/or an increase of the operational scope of a system for pressurized fluid by executing some calculations, for example by means of a computer or other electronic means, on possible virtual rearrangements of the piping network or system for pressurized fluid so to predict potential financial savings to be expected when such a rearrangement is implemented in reality.

In that way, different scenarios can be evaluated and compared with one another. The method is therefore a great help in making decisions about changes to the design of an already existing system for pressurized fluid, especially regarding an increase of the energy efficiency or a decrease of the energy consumption and/or the operational scope of the system for pressurized fluid to be expected. The method is not intended for designing a complete system for pressurized fluid from scratch.

Preferably, in the method different virtual rearrangements to the system for pressurized fluid are generated automatically. In another preferred method in accordance with the invention calculations of potential financial savings and comparisons between several such generated virtual rearrangements are executed in an automatic way.

The calculations are preferably based on a measurement and/or monitoring of actual pressure loads measured in real live conditions, during a typical duty cycle, in the already existing system for pressurized fluid. For example, the evolution of pressure at the main pipe inlet and at the different pipe outlets of the piping network can be monitored for that purpose.

An advantage of such a method according to the invention is that it allows for the detection of critical parts of the piping network with high pressure or flow needs and that with the method also measures can be taken in order to rearrange the piping network, so to render such a concerned part or parts of the piping network less critical.

Still another important advantage of such a method according to the invention is that a lot of energy can be saved and, as a consequence, operation costs, CO₂ emission, . . . can be reduced a lot.

In a preferred embodiment of a method of the invention, the method comprises at least the steps of:
a) generating a set of one or more theoretical piping networks (TPN) wherein a rearrangement on the system has been virtually applied;
b) calculating potential financial savings (PFS) for each possible virtual rearrangement of the system in the set;
c) keeping one or more of the calculated potential financial savings (PFS) and the corresponding virtual rearrangement of the system;
d) evaluating whether there is at least a single or there are multiple virtual rearrangements of the system in the set for which positive potential financial savings (PFS) were obtained during calculation or not;
e) if there is not any virtual rearrangement of the system in the set for which positive potential financial savings (PFS) were obtained during the calculation step, to stop the method; and,
f) if there is at least one virtual rearrangement of the system in the set for which positive potential financial savings (PFS) were obtained during the calculation step, propose one or more of the virtual rearrangements for which positive potential financial savings (PFS) were obtained during the calculation step to a user for implementation.

Such a method in accordance with the invention is very advantageous in that a decision on a modification of an existing system for pressurized fluid can be easily made with the aid of a computer or other electronic means and in a rational manner by comparing predictions or calculations made on virtually modified versions of that system for pressurized fluid.

Preferably the different virtual rearrangements of the system for pressurized fluid are automatically generated, for example by a computer or other electronic means, based on measurements of pressures in the existing system. Also the calculations are preferably based on such measurements and executed automatically by such a computer or other electronic means. In that way very realistic predictions of the performance of the system for pressurized fluid after modification can be made in a very quick manner.

In still another preferred method in accordance with the invention in step c) the highest potential financial savings (PFS) and the corresponding virtual rearrangement of the system is stored, for example in an electronic storing means such as a hard disk or other memory, and in step f) the virtual rearrangement of the system in the set with the highest potential financial savings (PFS) is proposed for implementation to a user, if at least this highest potential financial savings are positive.

Such a method in accordance with the invention has of course the advantage that from the set of the suggested, virtual rearrangements and analyzed rearrangements of the system for pressurized fluid the rearrangement which is the most promising for increasing the energy efficiency or reducing the energy consumption and/or the operational scope and the potential financial savings, is selected, preferably in an automatic manner, for example by a computer or other electronic means.

It is however not excluded from the invention to apply still other methods, for example a computer-implemented method wherein also the needed investment or capital expenditure for implementing the modification to the system for pressurized fluid is taken into account. It is for example possible that higher potential financial savings can be reached, but that the needed investment for implementation the corresponding rearrangement is too high to be still interesting for implementation.

In another method in accordance with the invention the step a) of generating a set of one or more theoretical piping networks (TPN) comprises the steps of:
h) determining a most critical pipe outlet of the piping network or of a formerly generated theoretical piping network (TPN);
i) evaluating whether an anomaly is occurring at the concerned most critical pipe outlet or not;
j) if no anomaly is found at the most critical pipe outlet, generating a theoretical piping network wherein the inlet pressure is virtually decreased; and,
k) if an anomaly is found at the most critical pipe outlet, generating a theoretical piping network with a virtually modified part in a portion of the piping network that leads to the most critical pipe outlet.

A first great advantage of such a method in accordance with the invention is that it comprises a step during which a most critical pipe outlet of the piping network or of a formerly generated theoretical piping network (TPN) is determined. Indeed, it is at that most critical pipe outlet that the potential for possibly reducing the pressure drop and, as a result for possibly decreasing the inlet pressure at the main pipe inlet and thus for possibly increasing the energy efficiency or reducing the energy consumption is probably the highest. Additionally or alternatively, it can be expected that in a portion of the piping network that leads to the most critical pipe outlet a modification or rearrangement of the piping network is most effective for increasing the energy efficiency or for reducing the energy consumption or for decreasing the pressure drop occurring over that portion, so to increase the operational scope of the system.

A second great advantage of such a method in accordance with the invention is that in a next step an evaluation is made whether an anomaly is occurring at the concerned most critical pipe outlet or not. Such an anomaly is present when the pressure at the most critical pipe outlet is dropping under the minimum pressure which is required at any time at the corresponding user location. Indeed, in that case there are occasions wherein no sufficiently high pressure is delivered at the concerned most critical pipe outlet, so that it is not ensured that the appliances at the corresponding user location can function at all times.

If no anomaly is detected, there is always a surplus pressure at the pipe outlets of the piping network, which signifies that the system for pressurized fluid can be improved by decreasing the inlet pressure. This is proposed as a step of the (computer-implemented) method.

On the other hand, if an anomaly is detected, the anomaly can possibly be remedied without a need for increasing the inlet pressure at the main pipe inlet, by modifying a portion of the piping network that leads to the most critical pipe outlet, which is proposed in another step of the concerned (computer-implemented) method.

Clearly, the proposed method according to the invention is a straightforward method for improving the system for pressurized fluid and is suitable for implementation on a computer or other electronic means.

In a preferred method in accordance with the invention, the step h) of determining a most critical pipe outlet of the piping network or of a formerly generated theoretical piping network (TPN) comprises the steps of:
l) determining for one or more pipe outlets the minimum pressure which is required at any time at the corresponding user location, so that operations at that user location can take place uninterruptedly;
m) determining a measuring period, corresponding to a typical duty cycle of the piping network, during which pressures at the main pipe inlet and the pipe outlets will be measured; and,
n) measuring or setting the inlet pressure at the main pipe inlet and measuring the pressure at the concerned pipe outlets during the measuring period.

Obviously, such a method in accordance with the invention is very practical in that it comprises the needed steps for getting the right information from the system by executing some measurements of pressure, which measurements allow to determine a most critical pipe outlet and to detect the presence or absence of an anomaly at that most critical pipe outlet. An additional advantage of such a method is that information is gathered from the existing system during operation, so that conditions in reality are taken into account when making calculations and predictions with respect to potential financial savings.

Preferably, the pressure at the main pipe inlet and at the concerned pipe outlets are measured in a synchronous way during the measuring period in step n) of the method.

It is of course only by simultaneously measuring the pressure at the main pipe inlet and at the concerned pipe outlets during a typical duty cycle that a correct view of the evolution is obtained of the real pressure drops occurring in the pressurized piping network.

Preferably, the pressure measurement is executed during the complete measuring period, for example in an analogue way, so that not any critical situation is missed of the presence of a high pressure need at the main pipe inlet, due to the simultaneous occurrence of high or maximum pressure loads at the pipe outlets during the duty cycle.

In a possible preferred embodiment of a method in accordance with the invention, the measurement of pressures during the measuring period in step n) of the method is a digital pressure measurement which is executed simultaneously at the different concerned pipe outlets and this at discrete points in time during the measuring period. The calculating and finding in further steps of the method are in this case executed on this group of discrete digital measurements.

An advantage of a digital measurement of pressure is that such a way of measuring results in digital data of the measured pressure, which type of data is more adapted for further processing with the currently available data processing means, such as a computer.

It is obvious that the discrete points in time should be sufficiently near to one another so that critical pressure load situations are not overlooked. This is at present not an issue anymore since high level electronic measuring devices are anywhere available.

Details of the measurements, the process for generating a set of theoretical piping networks, the calculations, the evaluation of the presence or absence of an anomaly at a most critical pipe outlet, the presenting of the most promising scenario or scenarios to a user and so on, will be elaborated further in the description be means of figures.

Preferably, a method in accordance with the invention is executed with electronic means and/or is a computer-implemented method.

A method according to the invention is typically also suitable for being implemented as a computer program which comprises instructions which, when the program is executed by a computer, cause the computer to carry out the method.

The present invention also concerns a data processing apparatus or computer comprising a processor and/or a computer program adapted to perform the steps of the method of the invention.

Furthermore, the present invention is also regarding a compressor, the compressor comprising a data processing apparatus or computer of the invention.

Finally, the present invention is also concerning a computer program comprising instructions which, when the program is executed by a computer, cause the computer to carry out a method in accordance with the invention.

### BRIEF DESCRIPTION OF THE DRAWINGS

The invention will further be illustrated with references to the drawings, wherein:

FIG. 1 is a schematic drawing of a system for pressurized fluid which comprises a piping network on which a method in accordance with the invention can be applied for improvement of the energy efficiency or reduction of the energy consumption and/or for increasing the operational scope of the system for pressurized fluid;

FIG. 2 illustrates a part of the piping network of FIG. 1, wherein a possible appliance at a pipe outlet of the piping network has been symbolized more in detail;

FIG. 3 illustrates on a very generalized level a flowchart of a method in accordance with the present invention for improvement of the efficiency and/or for increasing the operational scope of a system for pressurized fluid which comprises a pressurized piping network which is subjected to a varying load at some pipe outlets;

FIG. 4 illustrates in the form of a flowchart in more detail the step of the method of evaluating one or more virtual rearrangements of the piping network;

FIG. 5 illustrates in the form of a flowchart in more detail the steps which are involved in the execution of step a) represented in the flowchart of FIG. 4;

FIG. 6 illustrates in the form of a flowchart in more detail the steps which are involved in the execution of step h) represented in the flowchart of FIG. 5;

FIG. 7 gives more details about the steps i), j) and k) illustrated in the flow chart of FIG. 5;

FIG. 8 illustrates in the form of a flowchart in more detail the steps which are involved in the execution of step k) represented in the flowchart of FIG. 5;

FIG. 9 illustrates in the form of a flowchart in more detail the steps which are involved in the execution of step b) represented in the flowchart of FIG. 4;

FIG. 10 illustrates a first situation with a typical fluctuation of pressure measured at two pipe outlets of a piping network, without the occurrence of an anomaly, in particular in the situation before an improvement of the efficiency and/or an increase of the operational scope of the system for pressurized fluid with a method according to the present invention is realized;

FIG. 11 illustrates in a similar way as in FIG. 10 the calculated fluctuation of pressure that can be expected at the two pipe outlets of the piping network after the inlet pressure has been virtually decreased and after an optimization or improvement or a first step in such an improvement of the efficiency and/or an increase of the operational scope of the system for pressurized fluid with a method according to the present invention is executed;

FIG. 12 represents in a similar way as in FIG. 10 a second situation with another typical fluctuation of pressure, measured at two pipe outlets of a piping network, when an anomaly is occurring, and this again in the situation before an improvement of the efficiency and/or an increase of the operational scope of the system for pressurized fluid is obtained with a method according to the present invention;

FIG. 13 illustrates the theoretically calculated changes of pressure to be expected at one of the two outlets when the piping network behind the situation represented in FIG. 12 is virtually rearranged, for example by increasing a diameter of a pipe of the piping network; and, FIG. 14 depicts the expected situation corresponding to the one represented in FIGS. 12 and 13 at the two outlets after the virtual rearrangement of the piping network has been implemented and the inlet pressure has been virtually decreased and the efficiency of the system for pressurized fluid has been improved and/or the operational scope has been increased by means of a method in accordance with the invention.

### DETAILED DESCRIPTION OF EMBODIMENT(S)

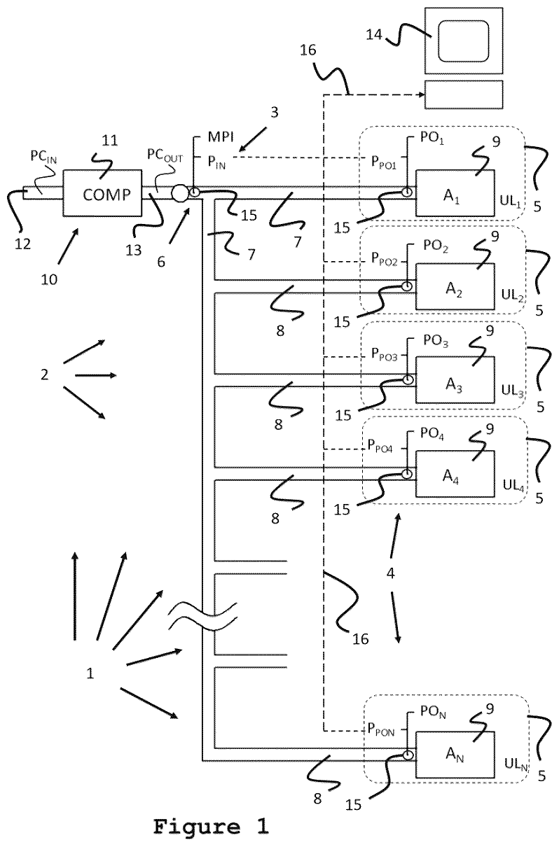

FIG. 1 illustrates a system for pressurized fluid 1 which comprises a piping network 2 which is provided with a main pipe inlet (MPI) 3 and multiple pipe outlets 4 (PO₁, PO₂, PO₃, . . . PO_{N}). In this case there are a number of N pipe outlets 4 in total.

The pipe outlets 4 are located at user locations 5 (UL₁, U₂, UL₃, . . . UL_{N}), which are spaced from one another and which are represented in FIG. 1 by means of a region surrounded by a dashed line. As explained in the introduction, the distance between the user locations 5 depends on the application and can be several meters or less to hundreds of meters and can even be one or more kilometers.

A main pipe piece 6 extends from the main pipe inlet 3. This main pipe piece 6 is branched into several pipe branches 7 and pipe subbranches 8.

Each pipe outlet 4 (PO₁, PO₂, PO₃, . . . PO_{N}) is connected to the main pipe inlet 3 (MPI) by means of a pipe formed by a combination of the main pipe piece 6 and a pipe branch 7 and possibly one or more pipe subbranches 8. In other configurations it is of course possible that still other subbranches are connected to a subbranch 8 and so on. The configuration of FIG. 1 is just an example.

User devices or appliances 9, which are indicated in FIG. 1 as A₁, A₂, A₃, . . . A_{N}, are provided at the user locations 5 and these user devices or appliances 9 are connected to the corresponding pipe outlet 4 of the concerned user location 5 with the intention of being supplied by means of the piping network 2 with pressurized fluid, typically pressurized air.

In the schematic drawing of FIG. 1 such an appliance 9 is represented by a square box, but in reality, such an appliance 9 can be any tool or device or combination of tools or devices that need(s) pressurized fluid.

For supplying pressurized fluid to the piping network 2 and through the piping network 2 to the appliances 9, at the main pipe inlet 3 of the piping network 2 fluid pressurized to an inlet pressure P_{IN} is provided by a source of pressurized fluid 10 of the system for pressurized fluid 1.

This source of pressurized fluid 10 is typically a compressor 11 (COMP) of the system for pressurized fluid 1, which is also the case in the embodiment of FIG. 1, but other sources could be used for this purpose.

The compressor 11 takes in uncompressed air at its inlet 12, typically at a pressure PC_{IN} which is the atmospheric pressure.

In the compressor 11 this air is compressed, and the compressed air is discharged at the outlet 13 of the compressor 11 at a higher pressure PC_{OUT}.

At the pipe outlets 4, the piping network 2 is subjected to a varying load due to varying demands of pressurized fluid during operation of the user devices or appliances 9, which are connected to the piping outlets 4 at the user locations 5.

FIG. 1 further illustrates that the system for pressurized fluid 1 also comprises a computer 14 or other electronic processing means, by which for example pressures P_{POi} measured at the pipe outlets 4 (POᵢ) or the inlet pressure P_{IN} measured at the main pipe inlet 3 and possibly still other measured or non-measured parameters can be processed.

For measuring the afore-mentioned pressures P_{IN} and P_{POi} or other pressures and possibly still other parameters, the system for pressurized fluid 1 comprises measuring means 15. Such a measuring means 15 can for example be a pressure gauge 15, which can be analog or digital pressure gauges, but other measuring means 15 such as temperature sensors or other sensors can be part of such measuring means 15.

Finally, the system for pressurized fluid 1 is also provided with communication means 16 for transferring the data or parameters measured with the measuring means 15 to the computer 15 or other electronic processing means. In the case of FIG. 1 these communication means are formed by a network of data cables 16 which connect the measuring means 15 with the computer 14. In other applications these communication means 16 can also be wireless and still other communication means 16 can be applied.

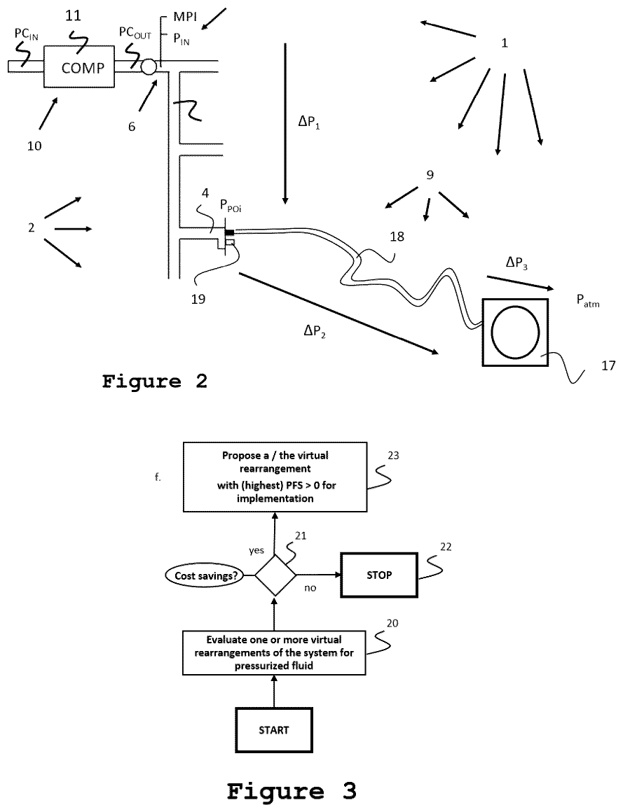

FIG. 2 illustrates more in detail the situation for one of the pipe outlets 4.

An appliance 9 is in this case represented by a pneumatically driven mechanical tool 17 that is connected by means of a flexible pneumatic hose 18 to the pipe outlet 4 of the piping network 2, from which pipe outlet 4 pressurized fluid is taken during operation with the mechanical tool 17.

At the same pipe outlet 4 there is also a valve 19 which is not connected to any appliance 9.

For purposes of introducing the reader into the problematics encountered in such a system 1 for pressurized fluid, let us now consider two situations.

In a first situation the mechanical tool 17 is not used and the valve 19 is opened without any (useful) load being applied at the valve 19.

In that case the pressure at or near to the pipe outlet 4 (P_{POi}) is the atmospheric pressure Pₐₜₘ and the part of the piping network 2 is exposed to a pressure difference P_{IN}−Pₐₜₘ which is the difference between a high pressure P_{IN}, which is equal to the outlet pressure PC_{OUT} of the compressor 11, and the atmospheric pressure Pₐₜₘ. By opening the valve 19 the fluid will accelerate in the pipe branches 7 and subbranches 8 to the pipe outlet 4 where it attains a certain velocity. As soon as the pressure ratio between the pressure P_{IN} at the main pipe inlet 3 and the atmospheric pressure Pₐₜₘ is big enough, i.e., when this ratio is higher than a critical minimum pressure ratio (which is for air around 1.89), the fluid starts to flow in so-called choked flow regime. In that case the fluid flows out of the concerned pipe outlet 4 at a maximum velocity which is equal to the speed of sound.

The total pressure drop ΔPₜₒₜ over the concerned pipe part is in this case equal to ΔPᵢ, which is the difference between P_{IN} and atmospheric pressure Pₐₜₘ or a certain critical pressure P_{c} in the case of choked flow. (ΔPₜₒₜ=P_{IN}−Pₐₜₘ or ΔPₜₒₜ=P_{IN}−P_{c}).

This pressure drop ΔP₁ over the concerned pipe part comprises a kinetic component, which is due to an increase of the velocity of the fluid in the piping network 1, as well as a pressure component which is caused by friction losses in the part of the piping network 2 that connects the main pipe inlet 3 with the concerned pipe outlet 4. It appears that in practice the kinetic component is negligible.

When the flow in this piping network 1 is supposed to be turbulent flow, the friction loss is more or less proportional with the square of the fluid velocity (v²) and more or less inversely proportional with the diameter of the concerned pipe.

A lot of other factors play a role, as has been explained in the introduction.

Nevertheless, one can understand that in this case the pressure must drop from the inlet pressure P_{IN} to the atmospheric pressure Pₐₜₘ or a critical pressure P_{c} in the case of choked flow. The pressurized fluid, such as pressurized air, reaches a relatively high velocity or even a velocity equal to the sound of speed, and high friction losses are involved. In this first case the following is valid: ΔP₁=ΔPₜₒₜ=P_{IN}−Pₐₜₘ Or ΔP₁=ΔPₜₒₜ=P_{IN}−P_{c}.

In the second situation valve 19 is closed and the mechanical tool 17 is used. In that case there is a pressure drop ΔP₃ over the mechanical tool 17, since pressurized fluid is used to do some mechanical work with the tool 17.

Furthermore, there is a pressure drop ΔP₂ in the flexible hose 18 which connects the mechanical tool 17 to the pipe outlet 4.

It is clear that in this case the total pressure drop ΔPₜₒₜ from the inlet pressure P_{IN} at the main pipe inlet 3 of the piping network 2 to the atmospheric pressure Pₐₜₘ at the outlet of the mechanical tool 17 is composed by three components: a first pressure drop ΔP₁ due to acceleration of the fluid and friction losses in the piping network 2, a second pressure drop ΔP₂ due to acceleration of the fluid and friction losses in the flexible hose 18 and a third pressure drop ΔP₃ which is the useful pressure for doing the mechanical work with the tool 17 (ΔPₜₒₜ=ΔP₁+ΔP₂+ΔP₃).

In this case the pressure P_{POi} at the pipe outlet 3 of the piping network 1 is somewhere between the inlet pressure P_{IN} and the atmospheric pressure Pₐₜₘ and depends on the characteristics of the flexible pneumatic hose 19 and pneumatic mechanical tool 17 and the use of that tool 17.

When the mechanical tool 17 or any other mechanical tool connected to the piping network 2 is not yet used and no pressurized fluid is flowing through the piping network 2, the pressure P_{POi} at the pipe outlet 4 of the piping network 2 is more or less equal to the inlet pressure P_{IN} at the main pipe inlet 3.

However, as soon as the mechanical tool 17 or any other mechanical tool connected to the network is being used, some pressurized fluid is flowing through the piping network 2 and also friction losses in the piping network 2 will occur.

Furthermore, as soon as the mechanical tool 17 is being used, some pressurized fluid is also flowing in the flexible hose 19 causing extra friction losses and work is done with the mechanical tool 17.

So, the pressure P_{POi} at the pipe outlet 4 will drop a bit and the more pressurized fluid is consumed by the mechanical tool 17, the more this pressure P_{POi} will drop.

It is clear that also consumption of pressurized fluid at other pipe outlets 4 of the piping network 2 than the pipe outlet 4 to which the mechanical tool 17 is connected have an influence on the pressure P_{POi} at that pipe outlet 4.

One can easily understand that at least some minimum pressure P_{POi}^{req} is always required at the pipe outlet 4 in order to provide sufficient pressurized fluid, when the mechanical tool 17 is used at its maximum capacity.

Normally, the piping network 2 is designed in such a way that the pressure drop ΔP₁ between the main pipe inlet 3 and the concerned pipe outlet 4 is limited, so that at the pipe outlet 4 always the required minimum pressure P_{POi}^{req} is available.

In practice however, the piping network 2 can be quite extended with many branches 7 and subbranches 8, with distances between the main pipe inlet 3 and the concerned pipe outlets 4 varying a lot, and with appliances 9 having all kinds of power needs which also can vary a lot in time.

From the above explanations, one understands that it is far from obvious to factor all the requirements and possibly changing demands already at the design stage.

A minimum required pressure P_{POi}^{req} at every pipe outlet 4 can be ensured by setting the pressure P_{IN} at the main pipe inlet 3 at a sufficiently high level.

A disadvantage of such a way of designing the piping network 2 is that the pressure P_{IN} at the main pipe inlet 3 is usually set at a level which is unnecessarily high, since appliances 9 are in practice never or almost never used simultaneously at their maximum capacity.

The higher the pressure P_{IN} at the main pipe inlet 3, the higher the pressure PC_{OUT} at the outlet pipe 13 of the compressor 11, the more energy is consumed by the compressor 11 and the higher the cost related to energy consumption will be.

In some cases, some anomalies may occur in the sense that the pressure P_{POi} delivered at one or more of the pipe outlets 4 of the piping network 2 can be too low, for example by a (temporary) lack of pressure P_{IN} at the main pipe inlet 3 and/or a (temporarily) too high demand of pressurized fluid at one or more of the pipe outlets 4. The occurrence of such anomalies can be avoided by changing the pressure at the main pipe inlet 3 or by changing the source of pressurized fluid 10. However, from a financial point of view it can often be better to redesign the system for pressurized fluid 1, for example by adapting the internal diameter of a part of the piping network 2 or by including one or more local pressure vessels in the piping network 2. The focus of the present invention is mainly on the last solution.

The present invention provides a method for improving or optimizing the efficiency and/or for increasing the operational scope of such a system for pressurized fluid 1 with a piping network 2 under a varying load at the pipe outlets 4, and this for an already existing system 1. In particular, such a method in accordance with the invention takes into account the real loads experienced at the pipe outlets 4 of the piping network 2 during a typical duty cycle. The method makes proposals for increasing the efficiency or the operational scope of the originally designed system 1 based on these data retrieved under real operational conditions of the system as designed. Furthermore, the method allows to set the pressure P_{IN} at the main pipe inlet 3 of the piping network 3 at a level which is not unnecessarily high.

Such a method in accordance with the invention will now be described more in detail.

FIG. 3 represents a flow chart describing the steps involved in a method in accordance with the invention in the most general terms.

In a method in accordance with the invention an evaluation is made of virtually created rearrangements of the original design of the system 1 and the potential financial savings PFS that can possibly be obtained related to those virtual rearrangements are calculated. This is represented in box 20 of the flow chart of FIG. 3.

The calculation is possibly based on a measurement of pressures or other parameters in the system 1 during operation.

Such a calculation of potential financial savings PFS, involves the calculation of cost reduction due to an increase in energy efficiency or a reduction of the energy consumption caused by such a rearrangement of the system 1 as well as the cost increase for implementing and maintaining such a rearrangement of the system.

Of course, only rearrangements which increase the energy efficiency or reduce the energy consumption, or the operational scope of the system 1 can contribute to cost savings PFS. Usually, the savings due to increased energy efficiency or due to reduced energy consumption are slowly accumulating during the operation and are dependent on the expected lifetime of the system 1. On the other hand, the implementation of a rearrangement of the originally designed system 1 is normally rather concentrated in a short period and should be increased by the cost for maintenance, which is often a cost which is recurring at regular time intervals. The cost of the implementation and the maintenance is therefore of another nature and can be spread by bank loans and so on. This means that the calculation of potential financial saving PFS can be highly dependent on the intended time of use of the concerned system for pressurizing a fluid 1.

Based on the made calculations the method in accordance with the invention furthermore evaluates whether there is any of the proposed virtual rearrangements of the system 1 that is expected to increase the efficiency or the operational scope of the system 1 in such a way that cost savings are to be expected. This step of evaluating the potential financial savings PFS of the method is represented by the rhombus shape 21 in FIG. 3.

If there is not any of the virtually created rearrangements which is expected to generate positive potential financial savings PFS, then the method is stopped, as is represented by box 22 in FIG. 3.

When there are one or more of the virtual rearrangements in the created set of virtual rearrangements, which are expected to generate potential financial savings PFS, in the method one or more of those virtual rearrangements are presented to a user for possible implementation. In a preferred method in accordance with the invention at least or only the virtual rearrangement corresponding to the highest to be expected potential financial savings PFS is presented to the user, but of course it is not excluded from the invention to provide the user with as many information as desired. This step of the method is represented in box 23 of FIG. 3.

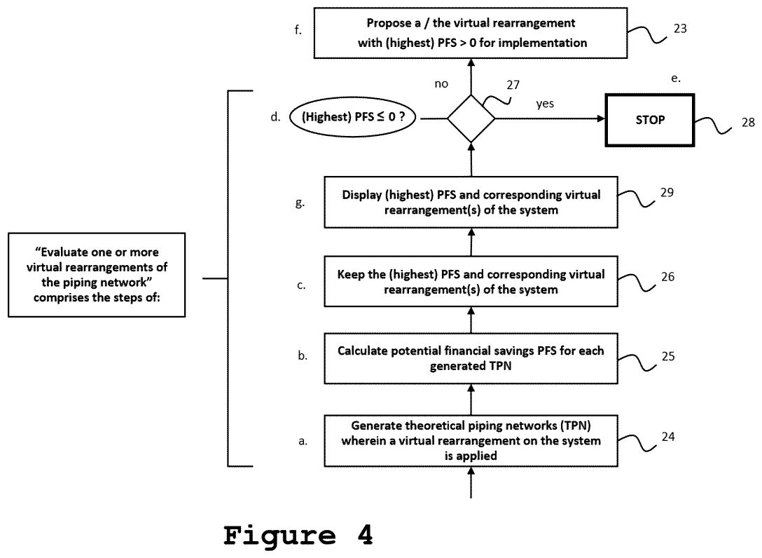

FIG. 4 illustrates a more detailed flow chart of the steps involved in the part of the method regarding the evaluation of one or more virtual rearrangements of the piping network 2 of the system for pressurized fluid 1.

In a first step a), which is represented in box 24 of FIG. 4, a set of one or more theoretical piping networks TPN are generated with or without a set of constraints, like building geometry, . . . wherein a rearrangement on the system 1 for pressurized fluid has been virtually applied. How these theoretical piping networks TPN are generated, will be discussed further in the text more in detail by means of other figures. In short, such a virtual rearrangement consists of at least a virtual decrease of the inlet pressure P_{IN} and comprises possibly, but not necessarily, also a virtual modification of the piping network 2 so to increase the energy efficiency or to reduce the energy consumption and to avoid the presence of an anomaly at one or more of the pipe outlets 4.

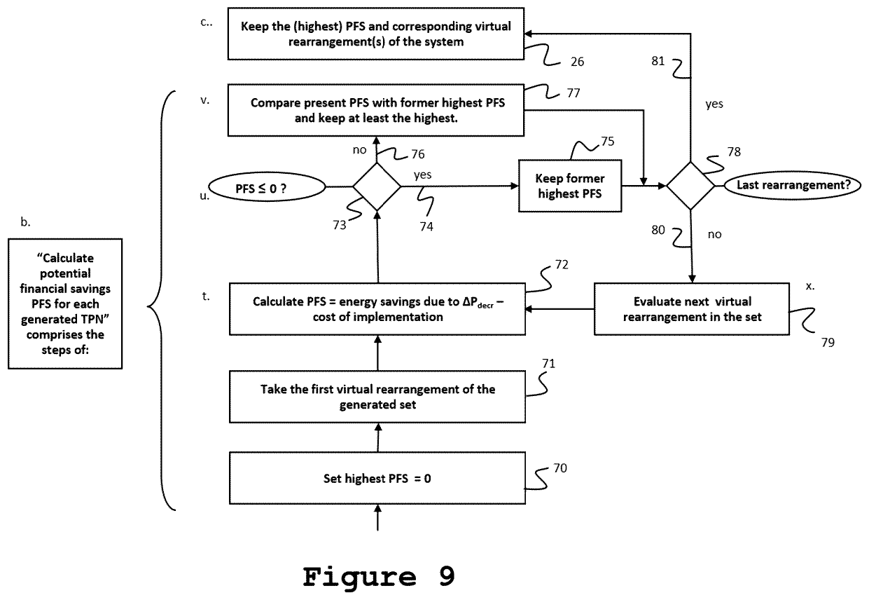

In a next step b), which is represented in box 25 of FIG. 4, potential financial savings PFS, which are expected to be possibly realizable after implementation, are calculated for each virtual rearrangement of the system 1 for pressurized fluid in the generated set of theoretical piping networks TPN. Details of a possible way of executing these calculations will be discussed further in the text by means of FIG. 9.

In still another step c) of the method according to the invention, which is represented in box 26 of FIG. 4, one or more of the calculated potential financial savings PFS, calculated in the preceding step b), and the one or more corresponding virtual rearrangements of the system 1 for pressurized fluid, are kept or stored, preferably in an electronic memory, such as a hard disk or any other storing means. In a preferred method in accordance with the invention at least the virtual rearrangement which is expected to generate the highest potential financial savings PFS and this highest potential financial savings PFS are stored in the memory.

The method furthermore comprises the additional step d), which is represented with rhombus shape 27 in FIG. 4, of evaluating whether there is at least a single or there are multiple virtual rearrangements of the system 1 for pressurized fluid in the generated set for which positive potential financial savings PFS were obtained during the calculation step b) or not.

In step e) of the method according to the invention, it is decided to abandon the execution of any further steps and thus to stop the method, if there is not any virtual rearrangement of the system 1 for pressurized fluid in the generated set for which positive potential financial savings PFS were obtained during the calculation step b). This step e) of the method is represented in box 28 of FIG. 4.

On the other hand, if there is at least one virtual rearrangement of the system 1 for pressurized fluid in the generated set of theoretical piping networks TPN for which positive potential financial savings PFS were obtained during the calculation step b), the step f) is executed, wherein one or more of the virtual rearrangements for which positive potential financial savings PFS were obtained during the calculation step b) is or are proposed to a user for implementation.

Obviously, in a preferred method in accordance with the invention at least the virtual arrangement which is expected to generate the highest potential savings PFS are proposed for implementation, if at least these highest potential savings PFS are positive. This step f) is represented in box 23 of FIG. 4 and corresponds to the step f) represented by box 23 in FIG. 3.

The method preferably also comprises a step g), which is represented in box 29 of FIG. 4, of presenting the calculated potential financial savings PFS and corresponding virtual rearrangement of the system 1 for pressurized fluid of one or more rearrangement(s) of the system 1 in the generated set to a user on a display unit.

In FIG. 4 this step g) precedes the step d) of evaluating the calculated potential financial savings PFS, but it is not excluded from the invention to execute the step g) of displaying results to a user after the evaluation made in step d). The results displayed in step g) of the method can include data about the evaluation made in step d) and can be presented in a way that some rearrangements are proposed to the user, for example in a ranking from a most interesting scenario to a least interesting scenario. There are of course multiple other possibilities.

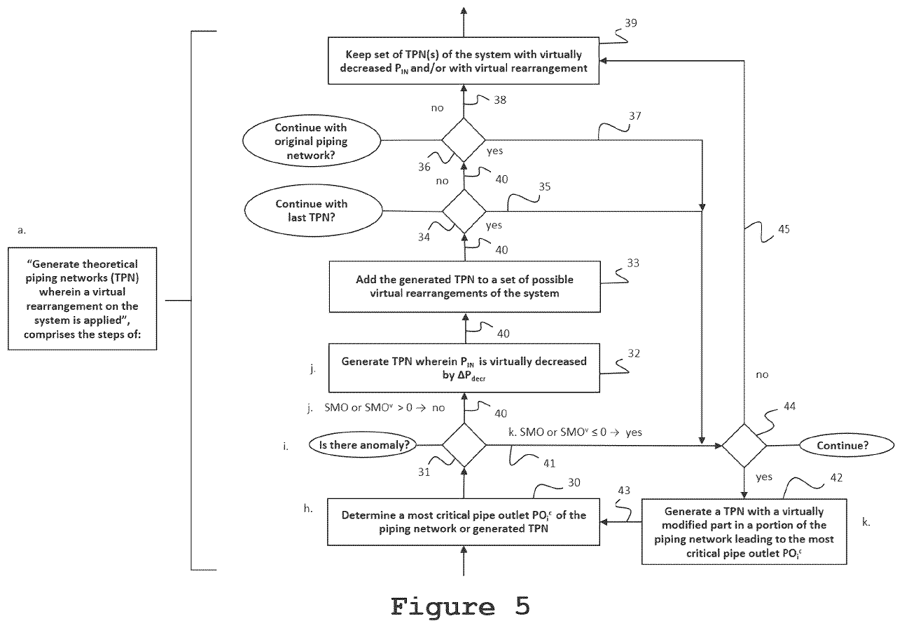

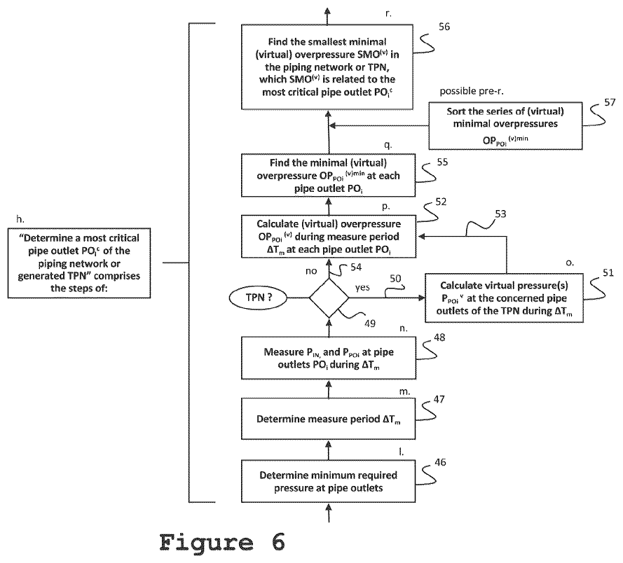

FIG. 5 is a flow chart illustrating the steps and the order in which these steps are executed involved in the execution of step a) of generating a set of one or more theoretical piping networks TPN, as represented in FIG. 4. This flowchart is still on a quite general level for a possible embodiment of a method according to the invention and details will be still more clarified by means of FIGS. 6 to 8 further in the text.

A first step involved in the generation of one or more theoretical piping networks TPN is the step h), which is represented at the bottom of FIG. 5 in box 30, of determining a most critical pipe outlet POᵢ^{c} of the piping network 2 or of a formerly generated theoretical piping network TPN.

Of course, at the initial start of this procedure of generating theoretical piping network TPN, in this step h) always the piping network 2 as it is in reality, will form the basis for generating a theoretical piping network TPN. It is only after having generated already one or more theoretical piping network(s) TPN that such a theoretical piping network TPN can possibly serve as a basis for generating still other theoretical piping networks TPN in this step h).

The steps possibly involved in determining a most critical pipe outlet POᵢ^{c} of the piping network 2 will be elaborated more in detail further in the text by means of FIG. 6. However, at this stage it can already be said that the pipe outlet POᵢ of the piping network 2 which is most critical is the pipe outlet POᵢ^{c} where the smallest minimal overpressure SMO or the smallest virtual minimal overpressure SMO^{v} among all the pipe outlets POᵢ is found.

This means that at the most critical pipe outlet POᵢ^{c} the overpressure is the lowest. This smallest minimal overpressure will be called a smallest minimal overpressure SMO or a smallest virtual minimal overpressure SMO^{v} dependent on whether the concerned pressure is a measured real pressure or a calculated pressure. This real or virtual overpressure is defined in such a way that it can be positive or negative, respectively corresponding to a situation where there is an excess of pressure at the concerned pipe outlet POᵢ^{c} or on the contrary a lack of pressure at that critical pipe outlet POᵢ^{c}.

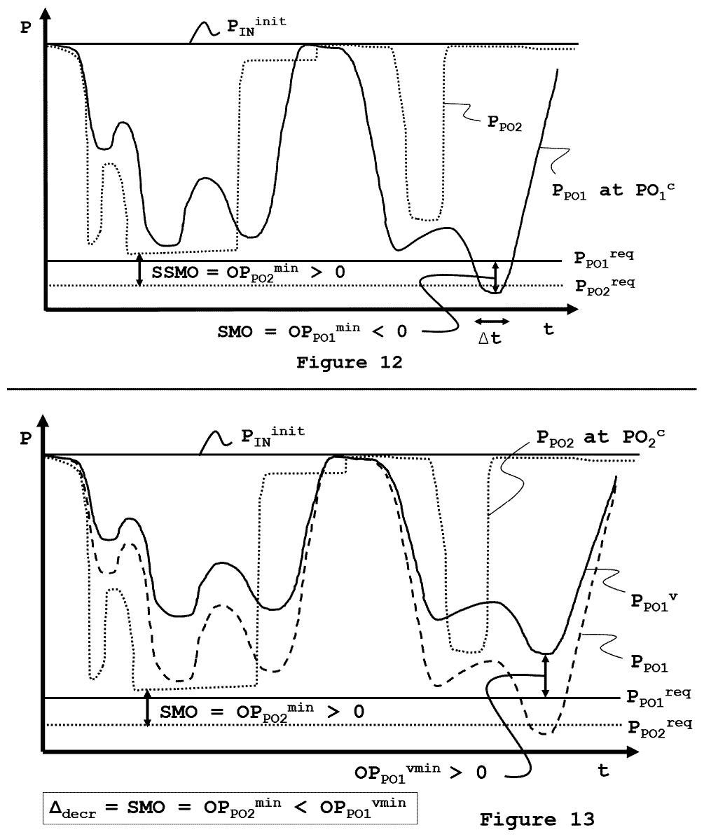

A next step involved in the generation of one or more theoretical piping networks TPN is the step i), which is represented by rhombus shape 31 in FIG. 5, of evaluating whether an anomaly is occurring at the concerned most critical pipe outlet POᵢ^{c} determined in step h) or not. As explained before, an anomaly is considered to be present, when during a certain time interval Δt the measured pressure P_{POi} or a calculated virtual pressure P_{POi}^{v} at the concerned determined most critical pipe outlet POᵢ^{c} plunges under the minimum pressure P_{POi}^{req} required at that pipe outlet POᵢ. This situation (see FIG. 12) corresponds to a lack of pressure (real or virtual) at that outlet POᵢ or to the presence of negative overpressure (real or virtual).

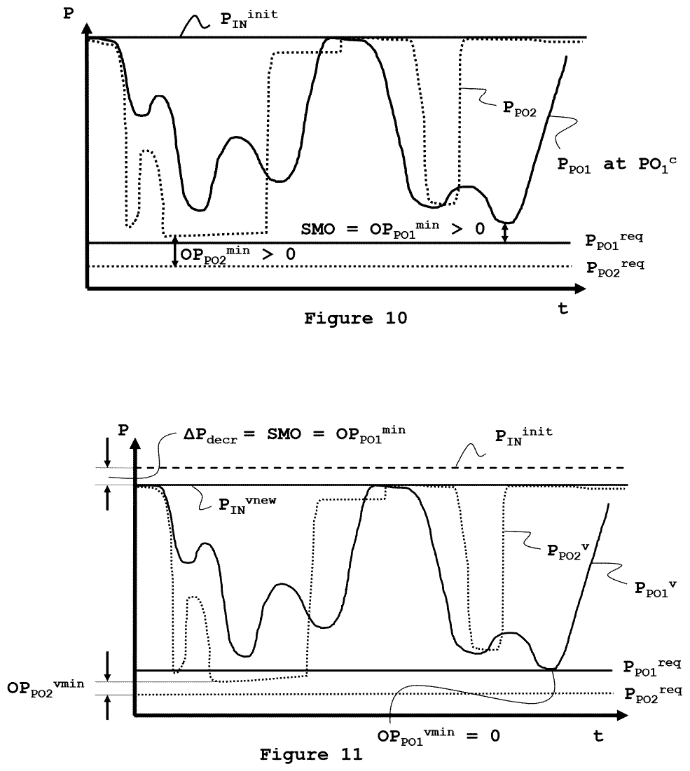

The situation wherein no anomaly is present at the most critical pipe outlet POᵢ^{c} corresponds to the case wherein the afore-mentioned smallest minimal overpressure SMO or smallest virtual minimal overpressure SMO^{v} at the most critical pipe outlet POᵢ^{c} is strictly positive, so that there is an excess of pressure (real or virtual) in the system 1 at all times. An example of such a situation is illustrated in FIG. 10, which depicts the evolution of measured pressure P_{PO1} and P_{PO2} over time during operation at two pipe outlets PO₁ and PO₂. In this example the first pipe outlet P_{O1} is the most critical pipe outlet P_{O1}^{C}.

If no such anomaly is found at the most critical pipe outlet POᵢ^{c}, the step j) is executed, which is represented by box 32 in FIG. 5, of generating a theoretical piping network TPN wherein the inlet pressure P_{IN} at the main pipe inlet 3 in the piping network 2 is virtually decreased by a certain amount ΔP_{decr}.

Since in this case even at the most critical pipe outlet POᵢ^{c} there is no anomaly, there is always some (real or virtual) excess pressure available at all the pipe outlets POᵢ of the piping network 2. As a consequence, the proposed virtual pressure decrease ΔP_{decr} of the inlet pressure P_{IN} at the main pipe inlet 3 for the theoretical piping network TPN can be chosen in such a way that, when the theoretical piping network TPN would be implemented, there is still no anomaly at the most critical pipe outlet POᵢ^{c} in the realized piping network 2.

This corresponds to a situation wherein the generated theoretical piping network TPN has a virtually decreased inlet pressure P_{IN}, and thus an increased energy efficiency or a reduced energy consumption, while it is still expected to be completely functional at all pipe outlets POᵢ during normal operation.

If in that case the determination step h) was executed on the original real piping network 2, the generated theoretical piping network TPN is the original piping network 2 with virtually decreased inlet pressure P_{IN}, while no other virtual rearrangement of the piping network 2 is further proposed.

On the other hand, if in that case the determination step h) was executed on an already formerly generated theoretical piping network TPN, the newly generated theoretical piping network TPN is the original piping network 2 with a virtually decreased inlet pressure P_{IN}, while also a virtual rearrangement of the piping network 2 is further proposed. This will become more obvious when other steps of the method are explained in more detail further in the text, in particular step k).

A next step in the method according to the invention, which is represented by box 33 in FIG. 5, consists of adding the generated theoretical piping network TPN with virtually decreased inlet pressure P_{IN} to a set of such generated theoretical piping networks TPN.

This means also that the set of theoretical piping networks TPN which are generated in the method is composed of theoretical piping networks TPN for which a virtual decrease of the inlet pressure P_{IN} is proposed. Moreover, according to the invention the proposed decrease of the inlet pressure P_{IN} is such that the system 1 for pressurized fluid would be functional at all pipe outlets POᵢ during the total duration of operation when the proposed virtual rearrangement of the system 1 would be implemented in practice.

Actually, it is according to the invention preferred to decrease the inlet pressure P_{IN} with the maximal possible amount ΔP_{decr} while keeping the system 1 for pressurized fluid still functional during the entire duration of operation.

It is however not excluded from the invention to execute the step j) by proposing a virtual decrease ΔP_{decr} of the inlet pressure P_{IN} with a greater amount, so to generate a theoretical piping network TPN wherein at one of the pipe outlets POᵢ a virtual anomaly or negative virtual overpressure OP_{POi}^{v} is virtually generated. This can be especially interesting in the step explained in the next paragraphs.

Indeed, rhombus shape 34 in FIG. 5 represents a possible step of a method in accordance with the invention, wherein an evaluation is taking place whether the generated theoretical piping network TPN will be used as basis for generating another theoretical piping network TPN or not.

When the generated theoretical piping network TPN serves as a basis for generating another theoretical piping network TPN (case of “yes”), then route 35 is followed.

The method further continues by the execution of step k) of generating a theoretical piping network TPN with a virtually modified part in a portion of the piping network 2 leading to the most critical pipe outlet POᵢ^{c}. Note that whenever the virtual pressure P_{POi}^{v} is needed for evaluating which pipe outlet POᵢ is the most critical outlet POᵢ^{c}, the virtual pressures Pₚₒᵢ^{v} at all the pipe outlets POᵢ, which are virtually decreased due to the proposed virtual decrease ΔP_{decr} of the inlet pressure P_{IN} at the main pipe inlet 3 are (re)calculated.

Furthermore, rhombus shape 36 in FIG. 5 indicates that a next step of the method can consist of an evaluation whether any more theoretical piping networks TPN should be generated or not based on the original piping network 2.

If so, route 37 of the flow chart is followed which again points to the same step k) of generating a theoretical piping network TPN with a virtual modification in a concerned part of the piping network 2.

Otherwise, the process of generating theoretical piping networks TPN is essentially terminated and route 38 of the flow chart is followed to the step, which is represented by box 39 in FIG. 5, and which consists of keeping the set of generated theoretical piping networks TPN with decreased inlet pressure P_{IN}.

Up to now, the vertical route through the flowchart of FIG. 5 has been explained, which corresponds to the route 40 followed when no anomaly was found at the most critical pipe outlet POᵢ^{c} in step i). However, still another important and essential step, i.e., step k) of the method, needs clarification, which is reached through route 41 of the flow chart.

Step k) of the method in accordance with the invention is executed when an anomaly is found at the most critical pipe outlet POᵢ^{c} in step i), which is the case when the smallest minimal overpressure SMO or the smallest virtual minimal overpressure SMO^{v} at that pipe outlet POᵢ^{c} is zero or negative (≤0). This case corresponds to the situation wherein during a certain time interval Δt the measured pressure P_{POi} or (calculated) virtual pressure P_{POi}^{v} at the most critical pipe outlet POᵢ^{c} drops below a minimum required pressure P_{POi}^{req} at that pipe outlet POᵢ^{c}.

An example of such a situation is illustrated in FIG. 12, which depicts the evolution of measured pressure P_{PO1} and P_{PO2} over time during operation at two pipe outlets PO₁ and PO₂. In this example the first pipe outlet P_{O1} is again the most critical pipe outlet P_{O1}^{c}.

In that case, in step k), which is represented by box 42 in FIG. 5, a theoretical piping network TPN is generated having a virtually modified part in a portion of the piping network 2 that leads to the most critical pipe outlet POᵢ^{c}. The aim of the virtual rearrangement is of course to take away the (possibly virtual) anomaly and to increase the energy efficiency or to reduce the energy consumption of the piping network 2 or the theoretical piping network TPN, for example by increasing a pipe diameter or by adding a local pressure vessel. Such a virtual rearrangement can also be a rearrangement by replacement of parts like filters, regulators, lubricators, valves or other components in the piping network.

In a preferred method according to the invention, the step k) of generating a theoretical piping network TPN with a virtually modified part in a portion of the piping network 2 that leads to the most critical pipe outlet P_{Oi}^{c} comprises the generation of a theoretical piping network TPN wherein the piping network 2 is virtually modified by an increase of the pipe diameter D of one or more parts of the piping network 2 between the main pipe inlet 3 and the most critical pipe outlet P_{Oi}^{c}.

In another preferred method according to the invention, the step k) of generating a theoretical piping network TPN with a virtually modified part in a portion of the piping network 2 that leads to the most critical pipe outlet P_{Oi}^{c} comprises the generation of a theoretical piping network TPN wherein the piping network 2 is virtually modified by an insertion of one or more local buffer vessels in a part of the piping network 2 between the main pipe inlet 3 and the most critical pipe outlet P_{Oi}^{c}.

After having generated such a theoretical piping network TPN with a virtual rearrangement of the piping network 2, the method is continued by again executing step h) and step i) on this generated theoretical piping network TPN, which is represented by route 43 in FIG. 5.

One should understand that in step i) of evaluating whether a certain anomaly is present or not at the most critical pipe outlet POᵢ^{c} of the generated theoretical piping network TPN, the conclusion is possibly still that an anomaly is present.

Actually, this means that the piping network 2 or virtual piping network TPN wherein the smallest virtual minimal overpressure SMO^{v} was already negative or zero in the preceding steps (see step i and k of the method in FIG. 5) by a lack of pressure P_{POi} or virtual pressure P_{POi}^{v} during a certain time interval Δt at the most critical pipe outlet POᵢ^{c}, still results in a negative or zero smallest virtual minimal overpressure SMO^{v} after introduction of the virtual rearrangement.

The reason can for example be that an increased pipe diameter D is chosen which is still not big enough in order to sufficiently reduce the pressure drop between the main pipe inlet 3 and the concerned most critical pipe outlet POᵢ^{c} in a way that no anomaly further occurs. As a consequence, in theory no really useful financial savings PFS can be realized with respect to the original situation.

However, in the case the “new” smallest virtual minimal overpressure SMO^{v} is “less” negative than the measured smallest minimal overpressure SMO or calculated smallest virtual minimal overpressure SMO^{v}, obtained in the preceding round (steps i and k), still a certain improvement of the efficiency of the system for pressurized fluid is obtained.

Indeed, in that case, by applying the proposed virtual rearrangement the increase of inlet pressure P_{IN} needed at the main pipe inlet 3 for avoiding lack of pressure or an anomaly occurring at any one of the pipe outlets POᵢ can be kept smaller than without applying the proposed virtual rearrangement of the piping network 2.

So, when it was decided to increase the inlet pressure P_{IN} for avoiding such an anomaly, it could from a financial point of view still make sense to apply the proposed rearrangement. This way of improving the system 1 for pressurized fluid is not excluded from the invention. Nevertheless, these possible steps are not represented in the flow charts of the figures.

In the case of the figures, the idea is to propose virtual rearrangements which solve the problem of anomaly and to decrease the inlet pressure P_{IN} accordingly in step j). It is possible that the steps h), i) and k) have to be repeated multiple times in order to find or generate a suitable virtual rearrangement.

Actually, during these steps h), i) and k) of the method of the invention the available or possibly realizable excess pressure in the system 1 for pressurized fluid is sought and then, it is proposed to decrease the inlet pressure P_{IN} with the available excess pressure.

In order to find this available excess pressure, preferably some measurements are made and dependent on the level of abstraction, i.e., dependent on the number of virtual parts or rearrangements included in the concerned generated theoretical piping network TPN, more or less estimations or calculations have to be made for finding the pressures which are expected to be present after implementation of the virtual rearrangement(s) in reality.

Finally, in FIG. 5 there is still another rhombus shape 44, representing an evaluation step, wherein it is evaluated whether the process of generating theoretical piping networks TPN should be continued or not, when it has been concluded that an anomaly is present in the piping network 2 or in the theoretical piping network TPN investigated during step h). When the process is stopped, route 45 of the flow chart is followed and the step represented in FIG. 39 is executed of keeping the already generated theoretical piping networks TPN with decreased inlet pressure P_{IN}. Otherwise, of course step k) is executed.

FIG. 6 is a flow chart illustrating more in detail possible steps involved when executing the step h), represented in box 30 of FIG. 5, of determining a most critical pipe outlet POᵢ^{c} of the piping network 2 or a previously generated theoretical piping network TPN.

A first step in the process of determining the most critical pipe outlet POᵢ^{c} is step l) of the method, which is represented in box 46 in FIG. 6. In this first step l) of the method, for one or more pipe outlets 4 the minimum pressure P_{POi}^{req} which is required at any time at the corresponding user location ULᵢ is determined, so that operations at that user location ULᵢ can take place uninterruptedly.

In another step m) of such a method according to the invention, which is represented in box 47 of FIG. 6, a measuring period ΔTm corresponding to a typical duty cycle of the piping network 2 is determined, during which pressure P_{IN} at the main pipe inlet 3 and the pressures P_{PO1}, P_{PO2}, P_{PO3}, . . . , P_{PON} at the concerned pipe outlets 4 will be measured.

In the next step n) of a method in accordance with the invention, which is described in box 48 of FIG. 6, the pressure P_{IN} at the main pipe inlet 3 is measured during the measuring period ΔTₘ and also the pressures P_{PO1}, P_{PO2}, P_{PO3}, . . . , P_{PON} at the concerned pipe outlets 4 are measured during the measuring period ΔTₘ.

Examples of such a measurement of pressures P_{PO1} and P_{PO2} during the measuring period ΔTₘ are represented in FIGS. 10 and 12 for two pipe outlets 4 of the piping network 2, respectively indicated with index 1 and index 2.

In a preferred method according to the invention, the pressure P_{IN} at the main pipe inlet 3 and the pressures P_{PO1}, P_{PO2}, P_{PO3}, . . . , P_{PON} at the concerned pipe outlets 4 are measured in a synchronous way during the measuring period ΔTₘ in step n) of the method.

This is preferred since it is in that manner that the total load to which the piping network 2 is subjected can be known at any moment in time in the most accurate way.

The fluctuation of the pressures P_{IN}, P_{PO1}, P_{PO2}, P_{PO3}, . . . , P_{PON} during the measuring period ΔTₘ can for example be determined in an analogue manner.

However, with the techniques of today in a preferred method according to the invention the measurement of pressures P_{IN}, P_{PO1}, P_{PO2}, P_{PO3}, . . . , P_{PON} during the measuring period ΔTₘ in step n) of the method is a digital pressure measurement which is executed simultaneously at the different concerned pipe outlets 4 and this at discrete points in time t₁, t₂, t₃, . . . during the measuring period ΔTₘ.

The discrete points in time t₁, t₂, t₃, should be near to one another compared relatively to the speed by which changes in load at the pipe outlets 4 of the piping network 2 occur, so that no situations with high load are missed during measurement of the pressures P_{IN}, P_{PO1}, P_{PO2}, P_{PO3}, . . . , P_{PON}.

In a preferred method in accordance with the invention the step h) of determining the most critical pipe outlet POᵢ^{c}, which step is represented in FIG. 5, additionally comprises also the following steps.

After having measured the concerned pressures in step n) an evaluation can be made, which is represented by rhombus shape 49 in FIG. 6, whether the piping network from which a most critical pipe outlet POᵢ^{c} has to be determined, is the original piping network 2 or is a previously generated theoretical piping network TPN.

If said concerned piping network 2 is a previously generated theoretical piping network TPN, route 50 in the flow chart of FIG. 6 is followed and in that case a possible next step in a method of the invention is step o), which is represented in box 51 of FIG. 6. This step o) consists of calculating the virtual pressure P_{POi}^{v} during the measuring period ΔTₘ at one or more pipe outlet(s) 4 of the theoretical piping network TPN for which the virtual modification or rearrangement of the piping network 2 is of concern.

This step o) is needed, since the pressure measurements P_{IN}, P_{PO1}, P_{PO2}, P_{PO3}, . . . , P_{PON} obtained in step n) of the method are representing the pressures P_{IN}, P_{PO1}, P_{PO2}, P_{PO3}, . . . , P_{PON} present in the real piping network 2. When introducing a virtual rearrangement in the piping network 2 at least at one or some pipe outlets POᵢ and possibly at all pipe outlets PO₁, not the measured real pressures P_{POi} should be considered, but calculated virtual pressures P_{IN}^{v} and/or P_{POi}^{v}, should be taken into account, when seeking the most critical pipe outlet POᵢ^{c} in that theoretical piping network TPN, wherein a virtual rearrangement on the real piping network 2 is proposed. Preferably, the pressures P_{IN}, P_{PO1}, P_{PO2}, P_{PO3}, . . . , P_{PON} measured during the measuring period ΔTₘ on the real piping network 2 in step n) serve as a basis for calculating the above-mentioned virtual pressures P_{IN}^{v} and/or P_{POi}^{v} during the measuring period ΔTₘ in the concerned theoretical piping network TPN. The pipe outlet POᵢ where such a virtual pressure P_{POi}^{v} should be calculated, are the pipe outlets POi that are expected to experience an important influence by the proposed virtual rearrangement of the piping network 2.

The method further proceeds with step p), which is illustrated by box 52 in FIG. 6, which is reached through route 53 of the flow chart in the case the piping network under investigation is the real piping network 2 or through route 54 after execution of step o). In this step p) the difference is calculated during the measuring period ΔTₘ between the usually varying pressures P_{POi} or virtual pressures P_{POi}^{v} at each concerned pipe outlet 4 and the corresponding minimum pressures P_{POi}^{req}, which are required at any time at the corresponding user location ULᵢ, so to find the corresponding overpressures OP_{POi} or virtual overpressures OP_{POi}^{v} at the concerned pipe outlet 4. These overpressures OP_{POi} or virtual overpressures OP_{POi}^{v} are usually also varying during the measuring period ΔTₘ.

The term overpressure OP_{POi} or virtual overpressure OP_{POi}^{v} should be understood correctly. Such an overpressure OP_{POi} or virtual overpressure OP_{POi}^{v} can be positive or negative, since it is the result of a subtraction between a measured pressure P_{POi} or a calculated virtual pressure P_{POi}^{v} at a pipe outlet 4 and the corresponding minimum required pressure P_{POi}^{req} at that pipe outlet 4.

This means that such an overpressure OP_{POi} or virtual overpressure OP_{POi}^{v} is possibly representing a “negative pressure” in the case the calculated result is negative.

In the example illustrated in FIG. 10 there are only positive measured overpressures OP_{PO1} and OP_{PO2} during the measuring period ΔTₘ, while in the example, which is illustrated in FIG. 12, the measured pressure P_{POi} at pipe outlet PO₁ is plunging under the minimum required pressure P_{POi}^{req} at that pipe outlet PO₁ during a certain time interval Δt within the measuring period ΔTₘ, so that the overpressure OP_{PO1} at the pipe outlet PO₁ is temporarily negative during that time interval Δt. The fact that during the time interval Δt the pressure P_{POi} at pipe outlet PO₁ is lower than the minimum required pressure P_{POi}^{req} at that pipe outlet PO₁ can be considered as being an anomaly of the normal operation conditions.

In a method in accordance with the invention, the process of determining a most critical pipe outlet P_{Oi}^{c}, comprises also a step q), which is represented by box 55 in FIG. 6, wherein for each concerned pipe outlet 4 (PO₁, PO₂, PO₃, . . . PO_{N}) the minimal overpressures OP_{PO1}^{min}, OP_{PO2}^{min}, OP_{PO3}^{min}, . . . and OP_{PON}^{min} or dependent on the concerned pipe outlet POᵢ the minimal virtual overpressures OP_{PO1}^{vmin}, OP_{PO2}^{vmin}, OP_{PO3}^{vmin}, . . . and OP_{PON}^{vmin} occurring or calculated during the measuring period ΔTₘ are sought so to obtain a series of minimal overpressures OP_{POi}^{min} or OP_{POi}^{vmin} composed of the minimal overpressures OP_{POi}^{min} or minimal virtual overpressures OP_{POi}^{vmin} of each concerned pipe outlet 4 (PO₁, PO₂, PO₃, . . . PO_{N}).

Finally, the process of determining a most critical pipe outlet P_{Oi}^{c}, comprises also a step r), which is represented in box 56 of FIG. 6, of finding the smallest minimal overpressure SMO or smallest virtual minimal overpressure SMO^{v} occurring in the piping network 2 or theoretical piping network TPN during the measuring period ΔTₘ. During this step r) the critical pipe outlet P_{Oi}^{c} is defined as being the pipe outlet P_{Oi} which is related to this smallest minimal overpressure SMO or smallest minimal virtual overpressure SMO^{v} occurring or calculated.

This smallest minimal overpressure SMO or smallest minimal virtual overpressure SMO^{v} is the overpressure of one of the pipe outlets 4 which has the lowest value in the series composed of the “real” minimum overpressures OP_{POi}^{min} existing in the real piping network 2 and the calculated virtual minimum overpressures OP_{POi}^{vmin} of concerned pipe outlets 4, which are influenced by the proposed virtual rearrangement of the piping network 2. As explained before, the “real” minimum overpressures OP_{POi}^{min} are defined by a subtraction of a measured pressure P_{POi} and the minimum required pressure at the concerned pipe outlet POᵢ. As a consequence, the “real” minimum overpressures OP_{POi}^{min} are in practice usually also calculated, but the minimum overpressures OP_{POi}^{min} correspond to something in reality.

In the example of FIG. 10 the smallest minimal overpressure SMO is the minimum overpressure OP_{POi}^{min} of pipe outlet PO₁, since this minimum overpressure OP_{POi}^{min} is in this case the smallest minimum overpressure SMO in the series of minimum overpressures consisting of only OP_{PO1}^{min} and O_{PO2}^{min}.

In the example of FIG. 12 the smallest minimum overpressure SMO is also the minimum overpressure OP_{PO1}^{min} of pipe outlet PO₁.

In this example of FIG. 12, the absolute value of the minimum overpressure OP_{PO1}^{min} occurring at pipe outlet POᵢ is maybe not smaller than the absolute value of the minimum overpressure OP_{PO2}^{min} occurring at pipe outlet PO₂, but in this case the minimum overpressure OP_{PO1}^{min} has a negative value and is therefore smaller than the minimum overpressure OP_{PO2}^{min}, which is a positive minimum overpressure OP_{PO2}^{min}.

So, the smallest minimum overpressure SMO is in this example again OP_{PO1}^{min}.

In a preferred method according to the invention the step r) is possibly preceded by a step pre-r), represented by box 57 in FIG. 6, wherein the series composed of minimum overpressures OP_{POi}^{min} and the concerned virtual minimum overpressures OP_{POi}^{vmin} of all the pipe outlets 4 is sorted according to increasing size from the smallest minimal overpressure SMO or smallest virtual minimal overpressure SMO^{v} to the biggest minimal overpressure SMO or biggest virtual minimal overpressure SMO^{v}.

In that case step r) of the method consists of simply taking the first value in the sorted series which is composed of minimum overpressures OP_{POi}^{min} and concerned virtual minimum overpressures OP_{POi}^{min} as the smallest minimum overpressure SMO or smallest virtual minimal overpressure SMO^{v} occurring or calculated at a concerned pipe outlet 4 during the measuring period ΔTₘ.

The determination of the smallest minimum overpressure SMO or smallest virtual minimal overpressure SMO^{v} is not only of importance for finding the most critical pipe outlet P_{Oi}^{c}, but plays also a role in step i), represented in FIG. 5, during which it is evaluated whether an anomaly is occurring at the concerned most critical pipe outlet POᵢ^{c} or not. Indeed, as explained before, this step i) consists of the evaluation whether the smallest minimal overpressure SMO or the smallest virtual minimal overpressure SMO^{v} occurring in the piping network 2 during the measuring period ΔTₘ is bigger than zero or not, respectively corresponding to the absence and the presence of an anomaly.

The determination of the smallest minimum overpressure SMO or the smallest virtual minimal overpressure SMO^{v} can also play a role in step j) of the method, also represented in FIG. 5, which is a step executed when there is no (real or virtual) anomaly found during step i).

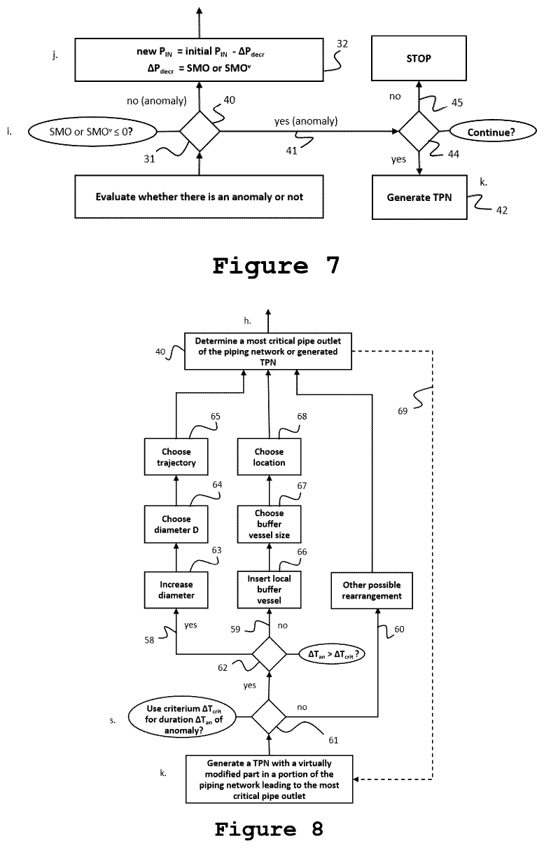

FIG. 7 is a flow chart in which the steps i), j) and k), are elaborated in more detail. From this flow chart it is clear that according to the invention, preferably, in step j) it is proposed to decrease the initial inlet pressure P_{IN}^{init} of the piping network 2 with an amount ΔP_{decr} which is equal to or slightly larger or slightly smaller than the smallest minimal overpressure SMO or the smallest virtual minimal overpressure SMO^{v} occurring or calculated in the piping network 2 or theoretical piping network TPN during the measuring period ΔTₘ.

In that way the inlet pressure P_{IN} at the main pipe inlet 3, which is the same as the compressor outlet pressure PC_{OUT}, is virtually set at a new inlet pressure P_{IN}^{vnew}, which is the initial inlet pressure P_{IN}^{init} from which the smallest minimal overpressure SMO or the smallest virtual minimal overpressure SMO^{v} or a slightly larger or slightly smaller pressure is subtracted (P_{IN}^{vnew}=P_{IN}^{init}−SMO or P_{IN}^{vnew}=P_{IN}^{init}−SMO^{v}).

The reason for choosing a decrease ΔP_{decr} which is equal to the smallest minimal overpressure SMO or the smallest virtual minimal overpressure SMO^{v} is of course that the smallest minimal overpressure SMO or the smallest virtual minimal overpressure SMO^{v} is a good estimate for the excess pressure, which is available or which is expected to be available in the piping network 2 during operation when implemented.

Usually, a piping network 2 is designed such that the pressure drop in the piping network 2 due to friction loss at its maximum load is not more than 3 to 5% over the entire pipe length from the main pipe inlet 3 to the concerned pipe outlet POᵢ.

In these conditions the smallest minimal overpressure SMO or the smallest virtual minimal overpressure SMO^{v} at the pipe outlets POᵢ is a good measure for the surplus of pressure available or expected to be available at the main pipe inlet 3 and the error made by this supposition is negligible in these conditions.

An advantage of such an embodiment of a method according to the invention is that the inlet pressure P_{IN} at the main pipe inlet 3 of the piping network 2 is set to a lower level, which is possible since the overpressure OP_{POi} or virtual minimal overpressure OP_{POi}^{v} at the pipe outlets POᵢ is bigger than zero during the entire operation time and in that manner energy and money are saved. The amount ΔP_{decr} by which the inlet pressure P_{IN} is decreased, is preferably chosen in such a way that during operation there will be still no anomaly or lack of pressure at not any of the pipe outlets POᵢ.

The reason why a slightly smaller amount of pressure Δ_{decr}⁻ can possibly be subtracted from the initial inlet pressure P_{IN}^{init}, is to preserve a small safety margin in order to ensure that the pressure P_{POi} at the concerned most critical pipe outlet POᵢ^{c}, after having decreased the initial inlet pressure P_{IN}^{init}, is kept at any time above the corresponding minimum required pressure P_{POi}^{req} at that pipe outlet POᵢ^{c}.

In the event that one does not need a safety margin, one can also subtract a slightly larger amount of pressure Δ_{decr}⁺ from the initial inlet pressure P_{IN}^{init}, so that one can maximize the energy yield at the expense of always having the minimum required pressure P_{POi}^{req} at that pipe outlet POᵢ^{c} available.

FIG. 8 is another flow chart which represents in more detail a possible implementation of the step k) of a method of the invention, which is represented in FIG. 5, wherein one or more theoretical piping networks TPN corresponding to virtual rearrangements of the piping network 2 are generated.

It is of course not excluded from the invention to implement this step k) in a completely different way.

Preferably, according to the invention, executing the step of the method, represented in FIG. 3, of evaluating one or more virtual rearrangements of the system 1 for pressurized fluid comprises an evaluation of the usefulness of a rearrangement of the piping network 2 which comprises an increase of the pipe diameter D of one or more parts of the piping network 2 between the main pipe inlet 3 and the most critical pipe outlet POᵢ^{c} where the smallest minimal overpressure SMO is measured or the smallest virtual minimal overpressure SMO^{v} is found, a corresponding theoretical piping network TPN being generated in step k of the method. This generation of such a TPN is represented by the route 58 in FIG. 8.

In another preferred method according to the invention the execution of the step, represented in FIG. 3, of evaluating one or more virtual rearrangements of the system 1 for pressurized fluid comprises an evaluation of the usefulness of a virtual rearrangement of the piping network 2 which comprises an insertion of one or more local buffer vessels in a part of the piping network 2 between the main pipe inlet 3 and the most critical pipe outlet POᵢ^{c} where the smallest minimal overpressure SMO is measured or the smallest virtual minimal overpressure SMO^{v} is found, a corresponding theoretical piping network TPN being generated in step k) of the method. This generation of such a TPN is represented by the route 59 in FIG. 8.

Still other possible virtual rearrangements of the piping network 2 and corresponding theoretical piping networks TPN can be generated, which is represented by route 60 in FIG. 7.

Sometimes it can be interesting to use an extra criterium for deciding whether a certain virtual rearrangement of the piping network 2 should be evaluated or not. This is also the case in the flow chart of FIG. 8.

Such a criterium can be based on the period ΔTₐₙ wherein the anomaly occurs at the concerned pipe outlet POᵢ with zero or negative smallest minimal overpressure SMO or smallest virtual minimum overpressure SMO^{v}.

This period ΔTₐₙ wherein the anomaly occurs, is the total duration, wherein the measured pressure P_{POi} or the calculated virtual pressure P_{POi}^{v} at the concerned pipe outlet POᵢ is lower than the minimum pressure P_{POi}^{req} which is required at any time at that pipe outlet POᵢ and/or at the corresponding user location ULᵢ.

Such a criterium is not necessarily used in a method according to the invention and whether or not the criterium is used can for example be decided in an additional step s) of the method, as is by way of example illustrated with the rhombus shape 61 in the flowchart of FIG. 8.

The used criterium can for example consist of an evaluation whether the period ΔTₐₙ wherein the anomaly occurs exceeds a certain pre-determined critical period of time ΔT_{crit} or not.

Such a possible use of an afore-mentioned criterium is by way of example illustrated with the rhombus shape 62 in the flowchart of FIG. 8.

For example, in a preferred method according to the invention, the step of the method, represented in FIG. 3, of evaluating a virtual rearrangement of the system 1 for pressurized fluid and wherein more specifically the usefulness of a virtual rearrangement of the piping network 2 by increasing a pipe diameter D of a portion of the piping network 2 has to be verified, is only executed when the period ΔTₐₙ wherein the anomaly occurs, exceeds said pre-determined period of time ΔT_{crit}. This corresponds to the route 58 in FIG. 8.

This makes sense, since the effort of replacing a whole pipe portion of the piping network 2 by a pipe portion with a larger diameter D is only efficient if the anomaly is big enough or is taking place during a sufficiently long period ΔTₐₙ longer than the pre-determined period of time ΔT_{crit}. Moreover, when the anomaly is occurring during a too long period ΔTₐₙ, the problem is not easily solved by inserting a local pressure vessel, since that would require a too big pressure vessel.

What's more, in still another preferred method according to the invention, the step of the method, represented in FIG. 3, of evaluating a virtual rearrangement of the system 1 for pressurized fluid and wherein more specifically the usefulness of a virtual rearrangement of the piping network 2 wherein a local buffer vessel is included in the piping network 2 has to be verified, is only executed when the period ΔTₐₙ wherein the anomaly occurs does not exceed said pre-determined period of time ΔT_{crit}. This corresponds to the route 59 in FIG. 8.

Also this kind of application of a criterium makes sense, for similar reasons. Indeed, the insertion of a local pressure vessel into the piping network 2 is only practically realizable when the duration of the anomaly ΔTₐₙ is not too big if at least its size should be kept within acceptable limits.

It is not excluded from the invention to incorporate the evaluation of the usefulness of still other virtual rearrangements of the piping network 2 for increasing its efficiency, for example virtual rearrangements which are a combination of the above-mentioned rearrangements by increasing a pipe diameter or including a local pressure vessel.

Another possible virtual rearrangement of the piping network 2 or system 1 for pressurized fluid could involve a relocation of the compressor 11 so to make the connection between the compressor 11 and the piping network 2 at another location, for example at a branch 7 or subbranch 8.

As an alternative, an additional source of pressurized fluid 10 or compressor 11 could be inserted into the piping network 2 and still other rearrangements of the piping network 2 could possibly be considered. This corresponds to the route 60 in FIG. 7.

Such additional evaluations of other virtual rearrangements of the piping network 2 can also be made dependent on still other criteria, but this is according to the invention also not necessarily the case.

A virtual rearrangement of the piping network 2 wherein a pipe diameter D is increased (box 63 in FIG. 8) can for example comprise the additional steps of selecting a specific increased pipe diameter D (box 64 in FIG. 8) and of choosing a pipe trajectory wherein this increased diameter D should be applied (box 65 in FIG. 8).

A virtual rearrangement of the piping network 2 wherein a local buffer vessel is inserted (box 66 in FIG. 8) can for example comprise the additional steps of choosing a specific pressure vessel size (box 67 in FIG. 8) and of choosing a specific location where the pressure vessel should be inserted (box 68 in FIG. 8).

Each generated theoretical piping network TPN in which a virtual rearrangement is proposed is then further analyzed and further adapted in steps h), i) and j) or k) of the method (see FIG. 5) which starts with step h) of determining the most critical pipe outlet P_{Oi}^{c} of the concerned theoretical piping network TPN. This is illustrated in FIG. 8 by means of box 40.

Several different possible theoretical piping networks TPN or virtual rearrangements of the system 1 of pressurized fluid can possibly be generated by repeating the process. This is represented by the route 69 in dashed line in FIG. 8, which line somewhat summarizes different possible paths in the flow chart of FIG. 5, which possibly result in the generation of multiple theoretical piping networks TPN in which a virtual rearrangement is proposed.

Finally, FIG. 9 illustrates with a last flow chart a possible more detailed implementation of the step b), represented in FIG. 4, of calculating potential financial savings PFS for each theoretical piping network TPN generated in step a).

Before the start of this calculation the highest potential financial savings PFS variable is set to be zero. This is represented in box 70 of FIG. 9. Furthermore, box 71 of FIG. 9 illustrates that the calculation of potential financial savings PFS for each theoretical piping network TPN is realized by iteration through the set of generated theoretical piping networks TPN and is started by firstly considering the first virtual rearrangement in the generated set.

The essential part of step b) of calculating potential financial savings PFS for a particular virtual rearrangement of the piping network 2 is represented in box 72 of FIG. 9 and consists of the step t) of subtracting the cost of implementation of the virtual rearrangement from the cost savings obtained due to a decrease of the inlet pressure P_{IN} by the proposed amount ΔP_{decr}. Of course, such an evaluation of costs and gains usually also involves the life expectancy or total expected operational period of the system for pressurized fluid.

The method comprises a further step u), represented by the rhombus shape 73 in the flowchart of FIG. 9, which consists of an evaluation whether the potential financial savings PFS calculated in step t) are positive or negative. When the potential financial savings PFS are negative, for example when the energy cost savings are too low or the implementation costs are too high, then obviously the proposed rearrangement is not suitable for improving the system 1 of pressurized fluid, so that the highest potential financial savings PFS calculated up to now should not be changed (see box 74 and route 75 in FIG. 9).

If the potential financial savings PFS currently calculated in step t) are positive, a comparison should be made with the highest potential financial savings PFS calculated up to now and the highest of both should be kept as the currently calculated highest potential financial savings PFS. This is illustrated at route 76 as a step v) in box 77 of FIG. 9.

Box 26 of FIG. 9 describes the step c) of the method, which corresponds to the same step c) in box 26 represented in FIG. 4, wherein at least the highest calculated potential financial savings PFS and the corresponding virtual rearrangement are kept. Of course, it is not excluded from the invention to store also other virtual rearrangements which are expected to generate lower potential financial savings PFS when implemented.

The steps t), u) and v) should be repeated for all the proposed or generated virtual rearrangements or theoretical piping networks TPN until the last virtual rearrangement is reached. Therefore, the method comprises a step x) in which the evaluation of a next virtual rearrangement of the generated set is initiated until the last virtual rearrangement has been reached. This is represented by rhombus shape 78, box 79 and route 80 in FIG. 9. The iteration through the entire set of generated theoretical piping networks TPN is stopped when the last virtual rearrangement is reached (route 81 which terminates at box 26 representing step c).

This results in different potential financial savings PFS and at least the virtual rearrangement which is related to the highest potential financial savings PFS is preferably stored in step c) and proposed for implementation in step f) (see FIGS. 3 and 4).

FIG. 10 illustrates the evolution of pressures P_{POi} and P_{PO2} respectively at two pipe outlets PO₁ and PO₂ and P_{IN} at the main inlet pipe 3 measured during the measuring period ΔTₘ in step n) of the method of the invention (see FIG. 6).

Clearly, the concerned pressures P_{POi} and P_{PO2} at those pipe outlets PO₁ and PO₂ stay above the corresponding minimum required pressures P_{PO1}^{req} and P_{PO2}^{req} which are needed at these pipe outlets PO₁ and PO₂ during operation as defined in step m) of the method of the invention (see again FIG. 6).

This means that the overpressure OP_{PO1} or OP_{PO2} at those pipe outlets PO₁ and PO₂, which is the difference between the concerned pressure P_{PO1} or P_{PO2} and the corresponding minimum required pressure P_{PO1}^{req} or P_{PO2}^{req}, is always a positive overpressure OP_{PO1} or OP_{PO2} during the entire measuring period ΔTₘ.

As a consequence, in the example of FIG. 10, at the pipe outlets POᵢ of the piping network 2 there is always an excess of pressure available than is strictly necessary for proper functioning at those pipe outlets POᵢ during the entire measuring period ΔTₘ. This corresponds also to a situation wherein no anomaly is detected during the measuring period ΔTₘ. (see steps i and j in FIG. 5)

Therefore, it is possible in this situation to decrease the inlet pressure P_{IN} at the main pipe inlet 3, without causing any anomaly or obstruction of the operations during a typical duty cycle, even after having decreased the inlet pressure P_{IN}. What is the maximum amount ΔP_{decr} by which the inlet pressure P_{IN} can be decreased without causing any anomaly during operation?

In a method according to the invention this is determined in a systematic way by first determining the most critical pipe outlet POᵢ^{c} of the piping network 2. (see step h in the flow chart of FIG. 5).

As defined in steps q) and r) (see FIG. 6) of a preferred method in accordance with the invention, the most critical pipe outlet POᵢ^{c} is the pipe outlet POᵢ where the smallest minimal overpressure SMO or the smallest minimal virtual overpressure SMO^{v} is observed or calculated.

In FIG. 10 the minimal overpressure OP_{PO1}^{min} and OP_{PO2}^{min} of the pressures P_{PO1} and P_{PO2} at the pipe outlets PO₁ and PO₂ are indicated in the graphs. Both minimal overpressures OP_{PO1}^{min} and OP_{PO2}^{min} are clearly positive (>0).

Furthermore, the minimal overpressure OP_{PO1}^{min} is smaller than the minimal overpressure OP_{PO2}^{min}, so that the minimal overpressure OP_{POi}^{min} is the smallest minimal overpressure SMO in this case, which consists of pressure measurements P_{PO1} and P_{PO2} at only two pipe outlets PO₁ and PO₂.

So, in the case represented in FIG. 10, the first pipe outlet PO₁ is the most critical pipe outlet P_{PO1}^{c}. (see step r in FIG. 6 and step h in FIG. 5).

Since there is no anomaly during the measuring period ΔTₘ or, what is the same, since the smallest minimal overpressure SMO is strictly positive, in step i) of the method according to the invention (see FIG. 5) it is decided to generate a theoretical piping network TPN wherein the inlet pressure P_{IN} is decreased by an amount ΔP_{decr} (see step j in FIG. 5).

This amount ΔP_{decr} of pressure decrease is usually chosen to be equal to the smallest minimal overpressure SMO or the smallest minimal virtual overpressure SMO^{v} as is illustrated in FIG. 7 (step j). The reason is of course that the smallest minimal overpressure SMO or the smallest minimal virtual overpressure SMO^{v} is a good estimate for the maximum pressure decrease possible without causing any anomaly in the piping network 2, if it is supposed that the operations are always executed in a more or less similar way and that the measuring period ΔTₘ is sufficiently long and thus representative for capturing the typical critical events occurring during operation.

As explained before, it is possible to decide in step j) to decrease the inlet pressure P_{IN} by an amount ΔP_{decr} which is slightly less or slightly more than the proposed amount ΔP_{decr} equal to the smallest minimal overpressure SMO or the smallest minimal virtual overpressure SMO^{v}, for example dependent on whether a certain risk factor is taken into account by respecting a certain safety margin or not. In another case it can be decided that it is not that important that certain operations should be always be ensured for hundred percent and it can be decided to decrease the inlet pressure P_{IN} by an amount ΔP_{decr} which is slightly more or substantially more than the proposed amount ΔP_{decr} equal to the smallest minimal overpressure SMO or the smallest minimal virtual overpressure SMO^{v}.

FIG. 11 illustrates in a similar way as in FIG. 10 the virtual pressures P_{PO1}^{v} and P_{PO2}^{v} in the proposed theoretical piping network TPN wherein the initial inlet pressure P_{IN}^{init} has been virtually decreased by an amount ΔP_{decr} which is equal to the measured smallest minimal overpressure SMO, which is the minimal overpressure OP_{PO1}^{min} measured at the first pipe outlet PO₁. The new virtual inlet pressure P_{IN}^{vnew} is indicated in the figure.

According to the invention this step of calculating the virtual pressures P_{PO1}^{v} and P_{PO2}^{v} is not strictly necessary, since it suffices to calculate the potential financial savings PFS of the proposed theoretical piping network TPN with decreased P_{IN}, as is indicated by step b) in FIG. 4. However, for purposes of clarifying what would happen if the inlet pressure P_{IN} is decreased, the pressures P_{PO1}^{v} and P_{PO2}^{v} at the concerned pipe outlets P_{PO1} and P_{PO2} are plotted in FIG. 11.

In this case the virtual pressures P_{PO1}^{v} and P_{PO2}^{v} are supposed to be calculated pressures based on the earlier measurements during the measuring period ΔTₘ, but a similar and possibly more accurate plot could have been obtained for example after having decreased the initial inlet pressure P_{IN}^{init} to a new inlet pressure P_{IN}^{new} in reality and having measured the pressures P_{PO1} and P_{PO2} at the pipe outlets P_{O1} and P_{O2} in reality during a new measuring period ΔTₘ.

It is clear that by the proposed reduction of the inlet pressure P_{IN} at the main pipe inlet 3 with an amount ΔP_{decr} which is equal to the measured smallest minimal overpressure SMO, or what is the same, a reduction of the outlet pressure PC_{OUT} at the outlet 13 of the compressor 11, the energy efficiency or the energy consumption of the system 1 for pressurized fluid, including the compressor 11, the piping network 2, . . . is improved or optimized.

Less energy is consumed when the compressor 11 is working at a lower outlet pressure PC_{OUT}, which results in lower operation costs as explained in the introduction.

FIG. 11 also illustrates the virtual pressures P_{PO1}^{v} and P_{PO2}^{v}, which are calculated respectively at pipe outlets PO₁ and PO₂ after having virtually applied the new virtual inlet pressure P_{IN}^{vnew}. These virtual pressures P_{PO1}^{v} and P_{PO2}^{v} are also reduced with approximately the same amount ΔP_{decr} corresponding to the smallest minimum overpressure SMO^{v} or the smallest minimal virtual overpressure SMO^{v} in the piping network 2, compared to the originally measured pressures P_{PO1} and P_{PO2} respectively at pipe outlets PO₁ and PO₂ when the initial inlet pressure P_{IN}^{init} was still applied.

Therefore, as can be seen in FIG. 11, after virtually applicating the new virtual inlet pressure P_{IN}^{vnew}, the overpressures OP_{PO1}^{v} and OP_{PO2}^{v} during operation are always positive or equal to zero, or, what is the same, there is virtually never a lack of pressure P_{PO1}^{v} and P_{PO2}^{v} at any of the pipe outlets PO₁ and PO₂, since these pressures P_{PO1}^{v} and P_{PO2}^{v} are always above the corresponding required minimum pressures P_{PO1}^{req} and P_{PO2}^{req}.

This is an indication that after optimization or improvement of the efficiency or reduction of the energy consumption of the system 1 for pressurized fluid, the operations executed with the appliances A1, A2, etc. . . . executed at the corresponding pipe outlets PO₁, PO₂, . . . of the piping network 2 can probably still take place uninterruptedly.

It is clear that, due to the virtually decreased inlet pressure P_{IN}^{vnew}, the minimum (virtual) overpressure OP_{PO1}^{(v)min} to be expected at the first pipe outlet POᵢ is zero or more or less zero. This is also indicated in FIG. 11.

Since in the case of FIG. 10 there was no anomaly at the pipe outlets PO₁, the proposed improvement of the piping network 2 can be obtained without any virtual or real rearrangement of the piping network 2, apart from the decrease of the inlet pressure P_{IN}^{init} with an amount ΔP_{decr}.

Nevertheless, as is indicated in FIG. 5 at rhombus shape 34 and with route 35, the proposed theoretical piping network TPN with decreased inlet pressure P_{IN} can also serve as a basis for generating another theoretical piping network in step k), represented by box 42 in FIG. 5.

In that case the pressures P_{PO1}^{v} and P_{PO2}^{v} at the concerned pipe outlets P_{PO1} and P_{PO2} should indeed be calculated or otherwise determined, so that the pressures P_{PO1}^{v} and P_{PO2}^{v} at the pipe outlets PO₁ and PO₂ after having virtually decreased the initial inlet pressure P_{IN}^{init} to a new inlet pressure P_{IN}^{vnew} are known and can be used in next steps of the method, wherein for example the most critical pipe outlet POᵢ^{c} for use in step k) is determined and so on.

So, let us now consider the case represented in FIGS. 10 and 11 wherein there is no anomaly. What has to be done according to the method of the invention after step a) wherein a theoretical piping network TPN is generated with a virtual inlet pressure P_{IN}^{vnew} which is decreased by an amount ΔP_{decr}, while further no virtual rearrangements are applied?

From FIG. 4 it is clear that step b) has to be executed of calculating the potential financial PFS for the concerned theoretical piping network TPN. The formula that is applied is illustrated in step t) represented in box 72 of FIG. 9.

The potential financial savings PFS are the energy savings obtained as a consequence of the virtually reduced inlet pressure P_{IN}^{vnew}, compared to the initial inlet pressure P_{IN}^{init}, from which the costs for implementation of the theoretical piping network TPN should be subtracted. In this case only the initial inlet pressure P_{IN}^{init} is decreased, so that there are essentially no implementation costs, apart from setting the compressor outlet pressure PC_{OUT} to a lower value, which is essentially a costless operation.

Therefore, the formula introduced in the introduction can be applied:

$$PFS = ( \frac{Δ p}{0.1} ) \times V \times {R}_{h} \times 0.35 \times 0.007 \times {C}_{e}$$

The different parameters are as follows:
Δp=ΔP_{decr}=pressure reduction at the outlet of the compressor
V=volume flow rate
Rₕ=running hours
Cₑ=cost of electricity

Clearly, this theoretical piping network TPN is a good candidate for being the one to be chosen in the case of absence of any anomaly at the piping outlets PO₁, since no implementation costs are involved, so that this theoretical piping network TPN could very well represent an improvement which is expected to generate the highest potential financial savings PFS.

Of course, possibly still other theoretical piping networks TPN are generated, for example through route 35 and 37 in the flow chart of FIG. 5, which include virtual rearrangements of the piping network 2 involving real implementation costs. In that case, these additionally generated theoretical piping networks TPN should be evaluated in steps t), u), v) and x) of the flowchart of FIG. 9. Possibly one of those additional theoretical piping networks TPN could be still more interesting for implementation. This could for example be the case when the energy savings obtained by a still lower inlet pressure P_{IN} made possible by a rearrangement of the piping network 2 is largely surpassing the costs of implementation of the concerned virtual rearrangement of the piping network 2.

Let us now consider the case wherein in step i) of the method represented in FIG. 5, it is determined that the smallest minimal overpressure SMO or the smallest minimal virtual overpressure SMO^{v} is zero or lower than zero. This is for example the case in the example of FIG. 12.

As is indicated in rhombus shape 44 of FIG. 5, in that case the next step can simply consist of making the decision that no further theoretical piping networks TPN are generated for improving or optimizing the efficiency of the system for pressurized fluid 1. The method is then continued with the evaluation of the already generated set of theoretical piping networks TPN (see route 44 and box 39 of FIG. 5).

As an alternative or additionally, when the smallest minimal overpressure SMO or the smallest minimal virtual overpressure SMO^{v} is zero or lower than zero, in step i) of the method it could also be decided to make an attempt of countering the apparently existing anomaly or lack of pressure at the concerned most critical pipe outlet POᵢ^{c} by increasing the initial pressure P_{IN}^{init} with an amount equal to or slightly lower or slightly higher than (the absolute value of) the smallest minimal overpressure SMO or the smallest minimal virtual overpressure SMO^{v}. In that case, the inlet pressure P_{IN}^{init} is set at a new inlet pressure P_{IN}^{new} which is sufficiently high to avoid the occurrence of any anomaly at the pipe outlets POᵢ during operation, due to lack of pressure at a concerned pipe outlet POᵢ. A disadvantage of such a practice is of course that the energy consumption or efficiency of the system for pressurized fluid 1 is not improved or optimized, but on the contrary that the energy consumption is increased, or the efficiency decreased. For that reason, this possibility is not indicated in the flow chart of FIG. 5.

However, in a more interesting implementation of a method in accordance with the invention, when the smallest minimal overpressure SMO or the smallest minimal virtual overpressure SMO^{v} is zero or lower than zero, in step k) of the method represented in box 42 of FIG. 5, a theoretical piping network TPN is generated with a virtually modified part in a portion of the piping network 2 leading to the most critical pipe outlet POᵢ^{c}. The virtual rearrangement of the piping network 2 is intended to take away the anomaly and to allow a decrease of the inlet pressure P_{IN} by implementation of the virtual rearrangement, just as in the case discussed with respect to FIGS. 10 and 11.

A concerned example is illustrated in FIGS. 12 to 14. FIG. 12 for example illustrates the fluctuation of pressure P_{PO1} and P_{PO2} respectively measured at pipe outlets PO₁ and PO₂ during the measuring period ΔTₘ. The pressure P_{POi} at pipe outlet PO₁ drops beneath the minimum pressure P_{POi}^{req} required at that pipe outlet PO₁.

This means that the operations at the first user location UL₁ could probably not be performed as required during the afore-mentioned time interval Δt due to a lack of sufficiently pressurized fluid and therefore, there is clearly an anomaly at pipe outlet PO₁ during time interval Δt. The time interval Δt is representing in this case the total duration ΔTₐₙ during which the anomaly is occurring, referred to before (see FIG. 8).

The overpressure OP_{PO1} turns out to be negative during the time interval Δt at pipe outlet PO1, while the overpressure OP_{PO1} is strictly positive during the entire measuring period ΔTₘ (no anomaly at pipe outlet PO₂).

The overpressure OP_{PO1} is at its lowest level at the point indicated by the minimum overpressure OP_{PO1}^{min}, i.e., at the point where the pressure curve P_{PO1} is maximally dropping under the line indicating the minimum pressure P_{PO1}^{req} required at that pipe outlet PO1.

This minimum overpressure OP_{POi}^{min} at pipe outlet PO₁ is of course also negative, while the minimum overpressure OP_{PO2}^{min} at pipe outlet PO₂ has a positive value. Therefore, the minimum overpressure OP_{PO1}^{min} at pipe outlet PO₁ is in this case the smallest minimum overpressure SMO and the minimum overpressure OP_{PO2}^{min} at pipe outlet PO₂ is the second smallest minimum overpressure SSMO.

In a method according to the invention first step h) is executed (represented in FIG. 5) during which the most critical pipe outlet POᵢ^{c} should be determined. The pipe outlet POᵢ which is related to the smallest minimum overpressure SMO is according to steps q) and r) of the flow chart of FIG. 6 the most critical pipe outlet POᵢ^{c}, which is in this case again the first pipe outlet PO₁^{c}.

Then, in the here discussed case of FIG. 12, during step i) it is decide that step k) of the method (both represented in FIG. 5) should be executed of generating a theoretical piping network TPN by virtually modifying a part between the main pipe inlet 3 and the pipe outlet POᵢ^{c}, since there is clearly an anomaly at the most critical pipe outlet POᵢ^{c} (SMO<0). The generation of such a virtually modified part can consist of a lot of things such as the increase of a pipe diameter D or the insertion of a local buffer vessel and the steps indicated in FIG. 8 could be taken as a guideline, but other way of generating such a theoretical piping network TPN are not excluded from the invention.

As explained, in FIG. 12 the pressure P_{POi} at pipe outlet PO₁ plunges during a time interval Δt under the minimum pressure P_{PO1}^{req} required at that pipe outlet POᵢ. The smallest minimum overpressure SMO is in this case negative and is represented by the minimum overpressure P_{PO1}^{min} occurring at pipe outlet PO₁. The time interval Δt is representing in this case the total duration ΔTₐₙ during which the anomaly is occurring, referred to before.

Of course, in other cases the pressure P_{POi} could for example plunge multiple times under the minimum pressure P_{PO1}^{req} required during time intervals Δt₁, Δt₂, . . . and as a result another total duration ΔTₐₙ of the anomaly should be taken into consideration, which is the sum of those time intervals Δt₁, Δt₂, . . . .

As explained before, as a criterium for choosing a type of rearrangement of the piping system 1 that could be interesting for improving its efficiency, this total duration ΔTₐₙ of the anomaly could for example be compared to a pre-determined critical period ΔT_{crit}.

In the case the total duration ΔTₐₙ of the anomaly is bigger than said pre-determined critical period ΔT_{crit}, it could be decided to evaluate a rearrangement of the piping network 2, which consists of increasing the pipe diameter D of a part of the pipes in the piping network 2. (see route 58 in FIG. 8)

In the other case wherein the total duration ΔTₐₙ of the anomaly is smaller than said pre-determined critical period ΔT_{crit}, it could be decided to evaluate a rearrangement of the piping network 2, which consists of inserting a local pressure vessel in the piping network 1. (see route 59 in FIG. 8)

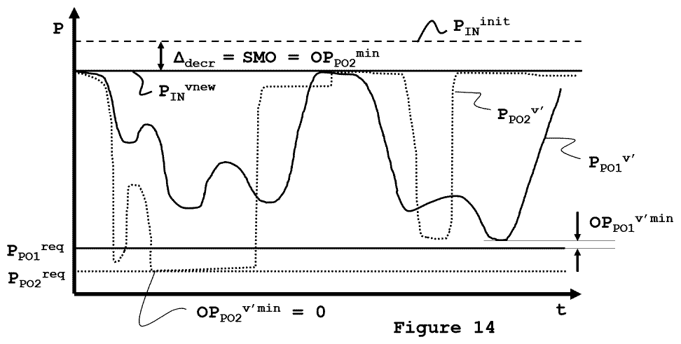

After the generation of the theoretical piping network TPN route 43 of the flow chart of FIG. 5 leads again to step h) of the method wherein again the most critical pipe outlet POᵢ^{c} has to be determined, but this time not on the initial unchanged real piping network 2, but on the generated theoretical piping network TPN. This is what is illustrated in FIG. 13.

As is indicated in FIG. 6 by means of rhombus shape 49, route 50 and box 51, in the case a most critical pipe outlet POᵢ^{c} has to be determined in a theoretical piping network TPN, first the virtual pressures P_{POi}^{v} should be calculated during the measuring period ΔTₘ at the pipe outlets POᵢ which are substantially influenced by the proposed virtual rearrangement.

Indeed, in such a theoretical piping network TPN a theoretical calculation can be made of the evolution of the virtual pressure P_{PO1}^{v} to be expected at the concerned pipe outlet, which is in this case pipe outlet PO₁, when the same kind of load is applied at that pipe outlet PO₁ as was the case during the measuring period ΔTₘ.

In the example of FIG. 13 the virtual pressure P_{PO1}^{v} at pipe outlet PO₁ is drafted during a hypothetical measuring period ΔTₘ as a curve P_{PO1}^{v}(t), since it is at the first pipe outlet PO₁ that the greatest modification of pressure is to be expected, since the virtual rearrangement consists of a modification of a portion of the piping network 2 between the main pipe inlet 3 and the most critical pipe outlet PO₁^{c}, which was the first pipe outlet PO₁, as determined during preceding steps of the method. In particular, (virtual) pressure augmentation is to be expected at pipe outlet PO₁ due to an improved performance of the piping network 2 under the virtual modification, causing for example less friction losses and therefore a smaller pressure drop over the concerned portion of the piping network 2.

The virtual pressure P_{PO1}^{v} is preferably based on the measured pressure P_{PO1} as illustrated in FIG. 12, which pressure P_{PO1} is also copied integrally on the chart of FIG. 13.

In this embodiment of a method in accordance with the invention it is proposed to calculate the virtual pressure P_{PO1}^{v} at the implicated pipe outlet PO₁ over the entire measuring period ΔTₘ, but of course it could for example suffice to calculate or determine the virtual pressure P_{PO1}^{v} only over a smaller period or at particular measuring points, for example only at the moment where the overpressure OP_{PO1} reaches its minimum OP_{PO1}^{min}, i.e., at the most critical point in time during the measuring period ΔTₘ or during the most critical conditions determined by the heaviest load at the concerned pipe outlet PO₁.

The outlet pressure P_{PO2} at the second pipe outlet PO₂ is supposed to be essentially unchanged by the proposed virtual rearrangement of the piping network 2 and is also integrally copied in the plot of FIG. 13.

For finding the most critical pipe outlet in the plot of FIG. 13, the steps p), q) and r) represented in FIG. 6 should now be applied on the curves in FIG. 13 representing the virtual pressure P_{PO1}^{v} at the first pipe outlet PO₁ and the measured pressure P_{PO2} at the second pipe outlet PO₂.

This time it appears that the minimal overpressure OP_{PO2}^{min} at the second pipe outlet PO₂, which is of course still strictly positive, is smaller than the minimal virtual overpressure OP_{PO1v}^{min} calculated at the first pipe outlet PO₁, which is also strictly positive. Therefore, in the plot of FIG. 13 the smallest minimal overpressure SMO is the minimal overpressure OP_{PO2}^{min} at the second pipe outlet PO₂. As a consequence, in this virtual configuration the second pipe outlet PO₂ becomes the most critical pipe outlet PO₂^{c} (see step r of FIG. 6).

The smallest minimal overpressure SMO is in this case strictly positive, which means that with the virtual rearrangement it is expected that no anomaly will anymore occur at the pipe outlets POᵢ. This means that step i) of the method, which is represented in FIG. 5, leads now to route 40 and step j) during which a theoretical piping network TPN is generated wherein the inlet pressure P_{IN} is decreased in a way completely similar as was elaborated with respect to FIGS. 10 and 11.

As is illustrated more in detail in FIG. 7, also in this case it is usually proposed to decrease the initial inlet pressure P_{IN}^{init} by an amount ΔP_{decr} which is equal to the smallest minimal overpressure SMO, which is in this case the minimal overpressure OP_{PO2}^{min} at the second pipe outlet PO₂, or the smallest minimal virtual overpressure SMO^{v}.

In other cases, the smallest minimal overpressure SMO can still be equal to or smaller than zero, and if so, it is decided in step i) of the method of the invention that the proposed virtual rearrangement of the piping network 1 is not eliminating the original anomaly and is considered as being not suitable for further improving the efficiency of the piping network 2.

FIG. 14 illustrates the situation to be expected after application of the proposed virtual rearrangement of the piping network 2 and after having virtually decreased the initial inlet pressure P_{IN}^{init} by an amount ΔP_{decr} so to become a new virtually decreased inlet pressure P_{IN}^{vnew}. The calculated virtual pressures P_{PO1}^{v′} and P_{PO2}^{v′} to be expected at the pipe outlets PO₁ and PO₂ as a result of the virtually decreased inlet pressure P_{IN}^{vnew} and the implementation of the virtual rearrangement are also plotted in FIG. 14. The energy savings to be expected from implementing the virtually decreased inlet pressure P_{IN}^{vnew} are calculated in a completely equivalent way, as explained with respect to FIGS. 10 and 11.

Step b) of the method, represented in FIG. 4, during which the potential financial savings PFS of the generated theoretical piping network TPN are calculated, requires this time however also the calculation of the cost of implementing the virtual rearrangement of the piping network 2 that brought the elimination of the original anomaly at the most critical pipe outlet POᵢ^{c} (see step t of FIG. 9).

This part of the calculation of the potential financial savings PFS can for example comprise calculations or estimations of a kind explained hereafter.

For example, if a diameter d₁ of a pipe piece in the piping network 1 is changed into a diameter d₂, the associated percentage of reduction of energy consumption can be calculated with the following formula:

$$\% {\dot{X}}_{el}^{reduction} = \frac{- ln [ 1 - \frac{Δ {p}_{1}}{{p}_{1}} ( 1 - \frac{{d}_{1}^{5}}{{d}_{2}^{5}} ) ]}{ln {p}_{1} - ln {p}_{atm}}$$

wherein
p₁=the initial discharge pressure over the concerned pipe piece;
Δp₁=the initial pressure drop over the concerned pipe piece;
% \dot{X}ₑₗ^{reduction}=percentage reduction of electric exergy rate.

The present invention is in no way limited to the embodiments of a for improving the efficiency and/or increasing the operational scope of a system 1 for pressurized fluid as described before, but such a method can be applied and be implemented in many different ways without departure from the scope of the invention.

The present invention is also not limited to embodiments of a data processing apparatus or computer, a compressor or a computer program as described in this text, but such a data processing apparatus or computer, such a compressor or such a computer program can be realized in very different manners without departure from the scope of the invention.

1-19. (canceled)

20. A method for improving the efficiency and/or increasing the operational scope of a system for pressurized fluid which comprises a pressurized piping network which is provided with a main pipe inlet and multiple pipe outlets which are located at user locations which are spaced from one another, wherein at the main pipe inlet of the piping network an inlet pressure is provided by a source of pressurized fluid of the system for pressurized fluid and wherein the piping network is subjected to a varying load at the pipe outlets due to varying demands of pressurized fluid during operation of user devices or appliances connected to the pipe outlets at the user locations, characterized in that the method comprises the evaluation of one or more virtual rearrangements of the system, which comprises virtual changes of operational conditions of the system such as pressure settings or flow rate settings and so on, and/or virtual modifications of the piping network such as virtually adding, removing, replacing and/or modifying components in one or more parts of the piping network, which evaluation furthermore involves:
a calculation of potential financial savings (PFS), due to an increase in energy efficiency or a reduction of the energy consumption caused by such a rearrangement of the system versus costs for rearranging the system, which calculation possibly involves a measurement of pressures in the system;
an evaluation of the potential financial savings (PFS); and,
if there are positive potential financial savings (PFS) proposing one or more virtual rearrangements for implementation to a user.

21. The method according to claim 20, wherein the method comprises at least the steps of:
a) generating a set of one or more theoretical piping networks (TPN) wherein a rearrangement on the system has been virtually applied;
b) calculating potential financial savings (PFS) for each possible virtual rearrangement of the system in the generated set;
c) keeping one or more of the calculated potential financial savings (PFS) and the corresponding virtual rearrangement of the system;
d) evaluating whether there is at least a single or there are multiple virtual rearrangements of the system in the set for which positive potential financial savings (PFS) were obtained during calculation or not;
e) if there is not any virtual rearrangement of the system in the set for which positive potential financial savings (PFS) were obtained during the calculation step, to stop the method; and,
f) if there is at least one virtual rearrangement of the system in the set for which positive potential financial savings (PFS) were obtained during the calculation step, propose one or more of the virtual rearrangements for which positive potential financial savings (PFS) were obtained during the calculation step to a user for implementation.

22. The method according to claim 21, wherein in the step c) the highest potential financial savings (PFS) and the corresponding virtual rearrangement of the system is stored and in the step f) the virtual rearrangement of the system in the set with the highest potential financial savings (PFS) is proposed for implementation to a user, if at least this highest potential financial savings (PFS) are positive.

23. The method according to claim 21, wherein the method comprises step g) of presenting the calculated potential financial savings (PFS) and the corresponding virtual one or more virtual rearrangement(s) of the system in the set to a user on a display unit.

24. The method according to claim 21, wherein the step a) of generating a set of one or more theoretical piping networks (TPN) comprises the steps of:
h) determining a most critical pipe outlet of the piping network or of a formerly generated theoretical piping network (TPN);
i) evaluating whether an anomaly is occurring at the concerned most critical pipe outlet or not;
j) if no anomaly is found at the most critical pipe outlet, generating a theoretical piping network (TPN) wherein the inlet pressure is virtually decreased with a certain amount; and,
k) if an anomaly is found at the most critical pipe outlet, generating a theoretical piping network (TPN) with a virtually modified part in a portion of the piping network that leads to the most critical pipe outlet.

25. The method according to claim 24, wherein the step h) of determining a most critical pipe outlet of the piping network or of a formerly generated theoretical piping network (TPN) comprises the steps of:
l) determining for one or more pipe outlets the minimum pressure which is required at any time at the corresponding user location, so that operations at that user location can take place uninterruptedly;
m) determining a measuring period, corresponding to a typical duty cycle of the piping network, during which pressures at the main pipe inlet and the pipe outlets will be measured; and,
n) measuring or setting the inlet pressure at the main pipe inlet and measuring the pressure at the concerned pipe outlets during the measuring period.

26. The method according to claim 25, wherein said step h) additionally comprises the steps of:
o) if the piping network is a theoretical piping network (TPN), calculating the virtual pressure during the measuring period at one or more pipe outlet(s) of the theoretical piping network (TPN) for which the virtual modification of the piping network is of concern, wherein o) consists of calculating the virtual pressure during the measuring period at one or more pipe outlet(s) of the theoretical piping network (TPN) for which the virtual modification or rearrangement of the piping network is of concern;
p) calculating the difference during the measuring period between the possibly changing measured pressure or calculated virtual pressure at each concerned pipe outlet and the corresponding minimum pressure which is required at any time at the corresponding user location, so to find the corresponding overpressure or virtual overpressure at the concerned pipe outlet which is possibly varying during the measuring period;
q) finding for each concerned pipe outlet the minimal overpressure or minimal virtual overpressure occurring during the measuring period so to obtain a series of minimal overpressures composed of minimal overpressures existing or measured at pipe outlets of the piping network and calculated minimal virtual overpressure(s) of concerned pipe outlets which are influenced by the proposed virtual rearrangement of the piping network; and,
r) finding the smallest minimal overpressure (SMO) or smallest minimal virtual overpressure occurring (SMOv) in the piping network or theoretical piping network (TPN) during the measuring period, the critical pipe outlet being the pipe outlet which is related to this smallest minimal overpressure (SMO) or smallest minimal virtual overpressure occurring (SMOv).

27. The method according to claim 26, wherein the step i) of evaluating whether an anomaly is occurring at the concerned most critical pipe outlet or not consists of the evaluation whether the smallest minimal overpressure (SMO) or the smallest virtual minimal overpressure (SMOv) occurring in the piping network during the measuring period is bigger than zero or not, respectively corresponding to the absence and the presence of an anomaly.

28. The method according to claim 24, wherein the step j) of generating a theoretical piping network (TPN) wherein the inlet pressure is virtually decreased when no anomaly is found at the most critical pipe outlet, consists of decreasing the inlet pressure of the piping network with an amount which is equal to or slightly larger or slightly smaller than the smallest minimal overpressure (SMO) or the smallest virtual minimal overpressure (SMOv) occurring or calculated in the piping network during the measuring period.

29. The method according to claim 24, wherein the step k) of generating a theoretical piping network (TPN) with a virtually modified part in a portion of the piping network that leads to the most critical pipe outlet comprises the generation of a theoretical piping network (TPN) wherein the piping network is virtually modified by an increase of the pipe diameter (D) of one or more parts of the piping network between the main pipe inlet and the most critical pipe outlet.

30. The method according to claim 24, wherein the step k) of generating a theoretical piping network (TPN) with a virtually modified part in a portion of the piping network that leads to the most critical pipe outlet comprises the generation of a theoretical piping network (TPN) wherein the piping network is virtually modified by an insertion of one or more local buffer vessels in a part of the piping network between the main pipe inlet and the most critical pipe outlet.

31. The method according to claim 29, further comprising step s) in which a criterium is used for deciding whether it is preferable to generate a theoretical piping network (TPN) with an increased pipe diameter (D) of a part of the piping network or with an inserted local buffer vessel.

32. The method according to claim 31, wherein the criterium is such that dependent on the total duration of anomaly, which is the total duration, wherein the measured pressure at the concerned most critical pipe outlet is lower than the minimum pressure which is required at any time at the corresponding user location, a theoretical piping network (TPN) is generated with an increased pipe diameter (D) of a part of the piping network or with an inserted local buffer vessel in a part of the piping network, respectively when the total duration of anomaly is exceeding a pre-determined period or when the total duration of anomaly is not exceeding a pre-determined period.

33. The method according to claim 24, wherein the step b) of the calculation of potential financial savings (PFS) for a particular virtual rearrangement of the piping network consists of a step t) of subtracting the cost of implementation of the virtual rearrangement from the savings obtained due to a decrease of the inlet pressure by the proposed amount.

34. The method according to claim 33, wherein after the step t) of calculating the potential financial savings (PFS) related to the implementation of a virtual rearrangement, the method comprises the following steps:
step u) of evaluating whether the potential financial savings (PFS) are positive or negative;
step v) of comparing the potential financial savings (PFS) calculated for the concerned virtual rearrangement with one or more formerly calculated potential financial savings (PFS) of one or more other virtual rearrangements; and
the step c) of keeping at least the highest calculated potential financial savings (PFS) and the corresponding virtual rearrangement.

35. The method according to claim 34, wherein the method comprises a step x) in which the evaluation of a next virtual rearrangement of the generated set is initiated until the last virtual rearrangement has been reached and wherein the steps t), u), v) and c) are repeated multiple times for the different virtual rearrangements of the piping network resulting in different potential financial savings (PFS) and wherein at least the rearrangement which is related to the highest potential financial savings is stored in step c) and is proposed for implementation in step f).

36. The method according to claim 20, wherein the method is executed with electronic means and/or is a computer-implemented method.

37. A data processing apparatus or computer, the data processing apparatus or computer comprising a processor and/or a computer program, which is adapted to perform the steps of the method of claim 20.

38. A compressor, wherein the compressor comprises a data processing apparatus or computer according to claim 37.
